(19) United States
(12) Patent Application Publication
(10) Pub. No.: US 2026/0013239 A1
(43) Pub. Date: Jan. 8, 2026

(54) SEMICONDUCTOR DEVICES WITH IMPROVED LEAKAGE CHARACTERISTICS AND METHODS FOR MANUFACTURING THE SAME

(71) Applicant: Taiwan Semiconductor Manufacturing Company, Ltd., Hsinchu (TW)

(72) Inventors: Sung-Hsin Yang, Hsinchu City (TW); Chen-Chieh Chiang, Hsinchu City (TW); Jia-Ren Chen, Hsinchu City (TW); Zhong-Yi Chen, Hsinchu City (TW)

(73) Assignee: Taiwan Semiconductor Manufacturing Company, Ltd., Hsinchu (TW)

(21) Appl. No.: 18/966,722

(22) Filed: Dec. 3, 2024

Related U.S. Application Data
(60) Provisional application No. 63/667,005, filed on Jul. 2, 2024.

(51) Int. Cl. H10F 39/18; H01L 21/762; H10D 30/62; H10D 64/27; H10F 39/00

(52) U.S. Cl. CPC H10F 39/182; H01L 21/76224; H10D 30/62; H10D 64/518; H10F 39/014

(57) ABSTRACT

A wafer configured as an ISP including a first area and a second area. The wafer, in the first area, comprises a first gate structure disposed around a first edge of a first active region and a second edge of a second active region extending along a first lateral direction and spaced from each other along the first lateral direction. The wafer, in the second area, comprises a second gate structure disposed around a third edge of a third active region and a fourth edge of a fourth active region extending along the first lateral direction and spaced from each other along the first lateral direction. The first gate structure has a first width along the first lateral direction and the second gate structure has a second width along the first lateral direction, the first width is substantially shorter than the second width.

### CROSS-REFERENCE TO RELATED APPLICATION

This application claims priority to and the benefit of U.S. Provisional Application No. 63/667,005, filed Jul. 2, 2024, entitled “SEMICONDUCTOR DEVICES WITH IMPROVED GIDL CHARACTERISTICS,” which is incorporated herein by reference in its entirety for all purposes.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example schematic diagram of an image sensor device, in accordance with some embodiments.

FIG. 2 illustrates another example schematic diagram of an image sensor device, in accordance with some embodiments.

FIG. 3 illustrates an example top or layout view of a portion of an image sensor device, in accordance with some embodiments.

FIG. 4 and FIG. 5 illustrate cross-sectional views of the portion of the image sensor device of FIG. 3, respectively, in accordance with some embodiments.

FIG. 6 illustrates another example top view of a portion of an image sensor device, in accordance with some embodiments.

FIG. 7 illustrates a cross-sectional view of the portion of the image sensor device of FIG. 6, in accordance with some embodiments.

FIG. 8 illustrates yet another example top view of a portion of an image sensor device, in accordance with some embodiments.

FIG. 9 illustrates a cross-sectional view of the portion of the image sensor device of FIG. 8, in accordance with some embodiments.

FIG. 10 illustrates a perspective view of a semiconductor device formed based on the layout shown in FIG. 3, in accordance with some embodiments.

FIG. 11 illustrates an example flow chart of a method for fabricating a semiconductor device, based on the layout shown in FIG. 3, in accordance with some embodiments.

FIGS. 12, 13, 14, 15, 16, 17, 18, 19, 20, 21, 22, 23, 24, 25, 26, 27, 28, 29, 30, and 31 respectively illustrate cross-sectional views of an example semiconductor device during various fabrication stages, made by the method of FIG. 11, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Complementary metal-oxide semiconductor (CMOS) image sensors are gaining in popularity over traditional charged-coupled devices (CCDs). A CMOS image sensor typically comprises an array of picture elements (sometimes referred to as pixels), which utilizes light-sensitive CMOS circuitry to convert photons into electrons. The light-sensitive CMOS circuitry typically comprises a photodiode formed in a silicon substrate. As the photodiode is exposed to light, an electrical charge is induced in the photodiode. Each pixel may generate electrons proportional to the amount of light that falls on the pixel when light is incident on the pixel from a subject scene. The electrons are converted into a (e.g., voltage) signal in the pixel and further transformed into a digital signal, which is generally processed by an application specific integrated circuit (ASIC) or an image signal processor (ISP).

A CMOS image sensor (CIS), or simply a CMOS sensor, may have a front side where a plurality of dielectric layers and interconnect layers are located connecting photodiodes in the substrate to the peripheral circuitry. A CMOS sensor is a front-side illuminated (FSI) image sensor if the light is from the front side of the sensor, otherwise it is a back-side illuminated (BSI) sensor with light incident on the backside. For a BSI sensor, light can hit the photodiode through a direct path without obstructions from the dielectric layers and interconnect layers located at the front side. This helps to increase the number of photons converted into electrons, and makes the CMOS image sensor more sensitive to the light source.

The image sensor market is being driven toward low cost, high image quality, and small camera module size, in accordance with the scaling trend of the in integration density. In general, an ISP and a CIS are first produced as two separated substrates, dies, or otherwise wafers, and are then bonded to each other. The ISP typically includes two types of circuits formed in areas of the corresponding substrate, respectively. For example, the ISP may include various core circuits and various input/output (I/O) circuits, in which, generally, the core circuits refer to a digital circuitry and the I/O circuits refer to an analog circuitry. The transistors of a core circuit may be operated with a lower voltage (e.g., by having a thinner gate dielectric layer), while the transistors of an analog circuit may be operated with a higher voltage (e.g., by having a thicker gate dielectric layer).

However, with the scaling trend, an amount of the leakage current, e.g., gate induced drain leakage (GIDL) current, arising from the analog circuitry has increased. Such increased leakage current disadvantageously impacts performance of the image sensor device such as, an increasing intensity of a random telegraph signal observed. This random telegraph signal is generally referred to as noise to the image sensor device. Although existing image sensor devices and methods of fabricating image sensor devices have been generally adequate for their intended purposes, as device scaling down continues, they have not been entirely satisfactory in certain respects.

The present disclosure provides various embodiments of a semiconductor device that can be implemented as a part of an image sensor device (e.g., an ISP). The semiconductor device, as disclosed herein, may include at least a first circuitry and a second circuitry, which correspond to a core circuitry and an input/output (I/O) circuitry, respectively. In some embodiments, the core circuitry and the I/O circuitry may be formed in a first area and a second area of a single substrate, respectively. The core circuitry and the I/O circuitry can be electrically coupled to each other through a number of metallization or interconnect layers formed over the substrate. In some other embodiments, the core circuitry and the I/O circuitry may be formed on a first substrate and a second substrate, respectively. The core circuitry and the I/O circuitry can be electrically coupled to each other through a number of first metallization layers formed over the first substrate and a number of second metallization layers formed over the second substrate. Further, to improve the leakage characteristic while maintaining the scaling trend, transistors of the I/O circuitry can be formed based on a combined (or coupled) edge gate structure (sometimes referred to as a combined poly on oxide diffusion edge (CPODE) structure), with a minimal overlap length between the CPODE structure and neighboring active regions. For example, by controlling the overlap length to be less than about 20 nanometers (nm) or even a negative value (e.g., down to about −20 nm), the leakage (e.g., GIDL) current can be suppressed up to about 40 times.

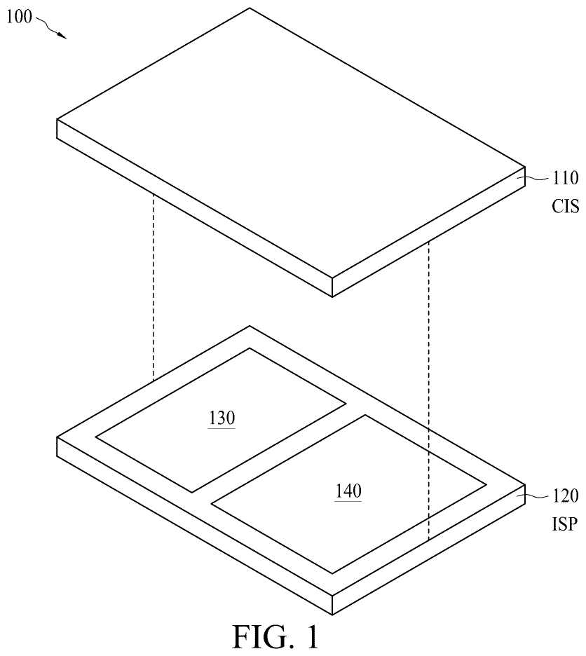

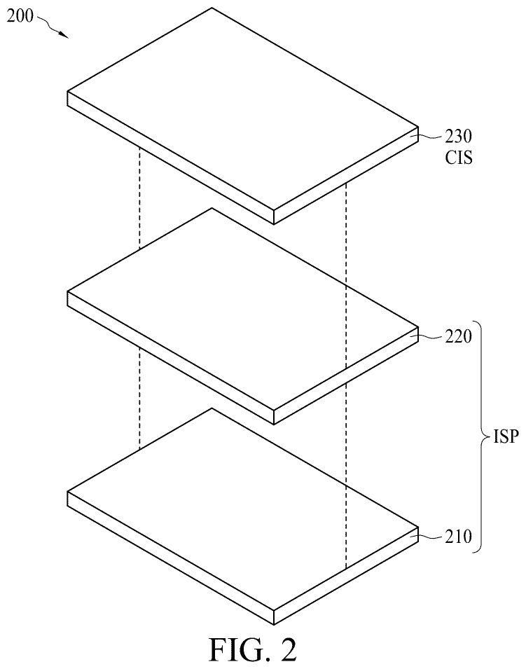

FIG. 1 and FIG. 2 respectively illustrate schematic diagrams of image sensor device 100 and image sensor device 200, in accordance with various embodiments. Each of the image sensor devices 100 and 200 can include a plural number of wafers (dies or substrates) bonded to one another, at least one which can include a number of pixels that operatively form a part of a CIS and at least another of which can include an analog circuitry that operatively forms a part of an ISP. It should be appreciated that the schematic diagrams of FIGS. 1-2 are provided merely for illustrative purposes, and thus, each of the image sensor devices 100 and 200 can include any of various other components while remaining within the scope of the present disclosure.

In FIG. 1, the image sensor device 100 includes a first substrate 110 and a second substrate 120. In some embodiments, the first substrate 110 can include a CIS, and the second substrate 120 can include an ISP. The first substrate 110 and the second substrate 120 can be operatively coupled to each other through a number of interconnect layers or structures (e.g., contact pads, a redistribution layer, bond pads, an interposer, etc.). Such interconnect layers/structures are not illustrated in FIG. 1 for brevity purposes.

The CIS can include a grid or array of pixels or sensor elements made on the first substrate 110. A pixel or a sensor element may be implemented as a photosensitive diode, or simply referred as a photodiode, connected to a transistor or to a plurality of transistors, which may be a transfer transistor, a reset transistor, a source follower transistor, or a select transistor. The photodiode may generate a signal related to the intensity or brightness of light that impinges on the photosensitive diode. The photodiode may be a pinned layer photodiode comprising a p-n-p junction. A non-pinned layer photodiode may alternatively be used. Any suitable photodiode may be utilized with the embodiments, and all of these photodiodes are intended to be included within the scope of the embodiments. The first substrate 110 may further include a plurality of isolation areas to separate and isolate various devices formed therein, and also to separate the pixels from other logic regions of the sensor.

In some embodiments, the ISP can include a core circuitry and an I/O circuitry, which can be formed in area 130 and area 140 of the substrate 120, respectively. The core circuitry, formed in the area 130, can include at least one of: a signal processing section/circuit, a digital signal processor (DSP), a memory, or a selector circuit. Further, the core circuitry can include a register, a subtracter, and the like that are provided within an analog-to-digital converter (ADC) and execute correlated double sampling (CDS) on the image signal converted into the digital value. Transistors formed in the area 130 can operatively serve as the above-identified core circuitry.

As a non-limiting example, the signal processing circuit (of the core circuitry) can execute various types of signal processing on digital image data either input from the ADC or read from the memory. In a case where the digital image data is a color image, the signal processing section can perform format conversion on this image data into YUV image data, RGB image data, or the like. The DSP (of the core circuitry) can function as a processing section that executes various types of processing through a learned model (sometimes referred to as a “neural network computing model”) created through the learning utilizing a deep neural network (DNN), by executing, for example, a program stored in the memory.

On the other hand, the I/O circuitry, formed in the area 140, can include at least one of: a part of the ADC (e.g., a comparator, a counter), a pixel circuit, a row driver, a control section/circuit, a phase locked loop (PLL) circuit, or a frequency division circuit. Transistors formed in the area 140 can operatively serve as the above-identified I/O circuitry. For example, the pixel circuit can read analog pixel signals from the CIS (formed on the first substrate 110), the row driver can drive the pixels of the CIS formed on the first substrate 110 per row arranged in a two-dimensional grid fashion in row and column directions, the comparator and the counter of the ADC can convert analog pixel signals read from the respective pixels into digital values, the PLL circuit can synchronize data with a master clock or the like input from the outside, and the frequency division circuit can divide a frequency of the master clock to generate a low frequency clock. The I/O circuitry may further include a reference voltage supply section provided within the control section and configured to supply a reference voltage to the comparator of the ADC.

In FIG. 2, the image sensor device 200 includes a first substrate 210, a second substrate 220, and a third substrate 230. In some embodiments, the third substrate 230 can include a CIS, the second substrate 220 can include an analog (or I/O) circuitry of an ISP, and third substrate 210 can include a digital (or core) circuitry of the ISP. The substrates 210 to 230 can be operatively coupled to each other through a number of interconnect layers or structures (e.g., contact pads, a redistribution layer, bond pads, an interposer, etc.). Such interconnect layers/structures are not illustrated in FIG. 2 for brevity purposes. The CIS, I/O circuitry of the ISP, and the core circuitry of the ISP, respectively formed in the substrates 210, 220, and 230, are substantially similar to the ones discussed with respect to FIG. 1, and thus, the discussion will not be repeated.

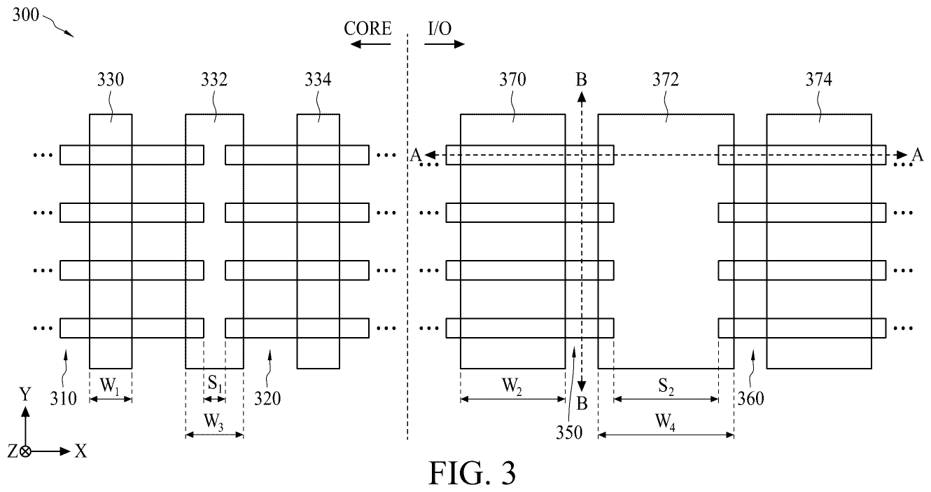

FIG. 3 illustrates a top or layout view 300 for forming an example semiconductor device, which includes a number of first structures (e.g., first active regions, first gate structures) for forming a core circuitry in a first area of a substrate and a number of second structures (e.g., second active regions, second gate structures) for forming an I/O circuitry in a second area of the substrate, in accordance with various embodiments. Such a semiconductor device may sometimes be referred to as “semiconductor device 300” in the following discussion.

In certain aspects, the semiconductor device 300 may be a non-limiting implementation formed based on a portion of a layout configured for forming the core circuitry and the I/O circuitry on the substrate 120 (FIG. 1). However, it should be appreciated that the layout view of FIG. 3 is merely an example, and thus, the substrate 120 that includes a core circuitry and an I/O circuitry can be configured in any of various other implementations while remaining within the scope of the present disclosure.

As shown, the layout 300 includes a first area configured for forming a core circuitry on a substrate (hereinafter “core area”), and a second area configured for forming an I/O circuitry on the substrate (hereinafter “I/O area”). Although, in FIG. 3, the core area and the I/O area seem to be adjacent to each other along the X-direction, it should be appreciated that the core area and the I/O area are not necessarily limited to be arranged with respect to each other along a certain direction. In the core area, the layout 300 includes a number of active regions 310 and 320, and a number of gate structures 330, 332, and 334; and in the I/O area, the layout 300 includes a number of active regions 350 and 360, and a number of gate structures 370, 372, and 374. It should be understood that the layout 300 can include any number of the same or other patterns in each of the core area and I/O area to form respective active regions or gate structures, while remaining within the scope of present disclosure.

The active regions 310, 320, 350, and 360 can extend along a first lateral direction (e.g., the X-direction), and the gate structures 330, 332, 334, 370, 372, and 374 can each extend along a second lateral direction (e.g., the Y-direction) perpendicular to the first lateral direction. In the core area, the active regions 310 and the active regions 320 can be spaced apart from each other along the X-direction with a spacing (S₁), and the active regions 350 and the active regions 360 can be spaced apart from each other along the X-direction with a spacing (S₂). In some embodiments, the spacing S₁ is substantially shorter than the spacing S₂.

In the core area, the gate structures 330 and 334 can traverse the active regions 310 and 320, respectively, while the gate structure 332 can traverse both of the active regions 310 and 320. Specifically, the gate structure 332 can overlay a longitudinal end portion of the active regions 310 (e.g., by covering a portion of a top surface of the active regions 310 adjacent one of the ends of the active regions 310 and by extending along a sidewall of the active regions 310 that faces the active regions 320); and the gate structure 332 can overlay a longitudinal end portion of the active regions 320 (e.g., by covering a portion of a top surface of the active regions 320 adjacent one of the ends of the active regions 320 and by extending along a sidewall of the active regions 320 that faces the active regions 310). In other words, each of the gate structures 330 and 334 can traverse a portion of the corresponding active regions, with a pair of other portions disposed on the lateral sides of itself, while the gate structure 332 can traverse each of the neighboring (yet spaced) active regions, with another portion disposed on one lateral side of itself.

Similarly, in the I/O area, the gate structures 370 and 374 can traverse the active regions 350 and 360, respectively, while the gate structure 372 can traverse both of the active regions 350 and 360. Specifically, the gate structure 372 can overlay a longitudinal end portion of the active regions 350 (e.g., by covering a portion of a top surface of the active regions 350 adjacent one of the ends of the active regions 350 and by extending along a sidewall of the active regions 350 that faces the active regions 360); and the gate structure 372 can overlay a longitudinal end portion of the active regions 360 (e.g., by covering a portion of a top surface of the active regions 360 adjacent one of the ends of the active regions 360 and by extending along a sidewall of the active regions 360 that faces the active regions 350). In other words, each of the gate structures 370 and 374 can traverse a portion of the corresponding active regions, with a pair of other portions disposed on the lateral sides of itself, while the gate structure 372 can traverse each of the neighboring (yet spaced) active regions, with another portion disposed on one lateral side of itself.

The gate structures 330, 334, 370, and 374 can each correspond to an active (e.g., metal or polysilicon) gate structure, while the gate structures 332 and 372 can each correspond to a dummy (e.g., metal or polysilicon) gate structure. For example, the gate structures 330, 334, 370, and 374, together with their traversed active regions, can operatively form functional transistors, while the gate structures 332 and 372, even with their traversed active regions, may not operatively form a functional transistor. Being formed along the edge of at least one active region, the gate structures 332 and 372 are sometimes referred to as a CPODE structure. In some embodiments, the active regions 310-320 and 350-360 and the gate structures 330-334 and 370-374 can be formed along the major surface of a substrate, and are sometimes referred to as part of front-end-of-line (FEOL) processing.

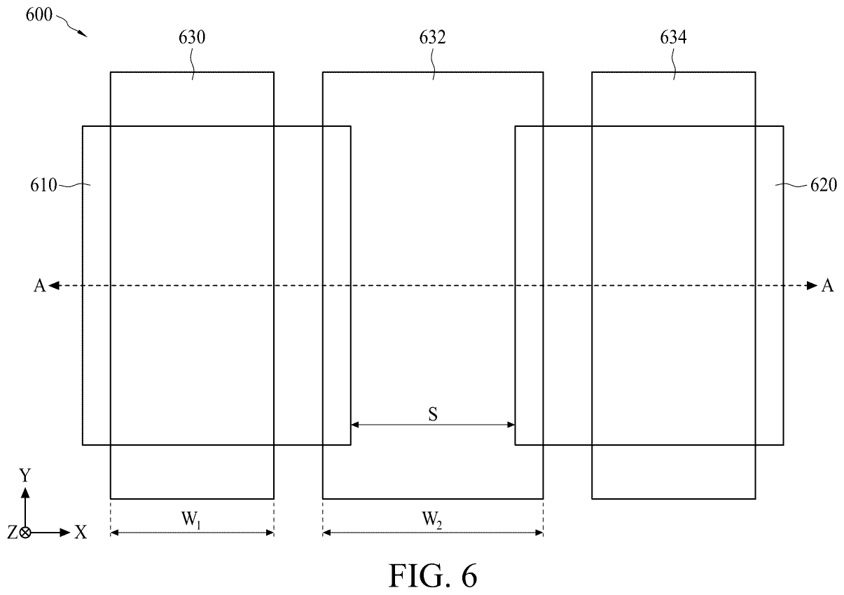

The transistors formed by the active regions and the gate structures of the layout 300, as discussed above, may each be configured as a fin-like field effect transistor (FinFET) structure. However, the layout 300 can be utilized to form other transistor structures such as, for example, a gate-all-around (GAA) transistor structure. Further, analogous to the layout 300, different layouts can be utilized to form the transistors of the core circuitry and an I/O circuitry on the substrate 120 in other transistor structures, which will be discussed in the examples of FIGS. 6-9 below.

In the implementation of FinFET structures, the active regions 310, 320, 350, and 360 can each be formed as a fin-like structure protruding from the frontside of a substrate. In general, the active regions 310, 320, 350, and 360 may have the same material as the substrate. The active regions 310 can have a plural number of fin-like structures extending in the X-direction and disposed parallel with one another. The active regions 320, 350, and 360 can be formed similarly, Further, respective portions of the fin-like structures that are overlaid by each of the gate structures 330-334 and 370-374 remain, while other portions are replaced with a number of epitaxial structures.

The remaining portion of the fin-like structure can be configured as the channel of a corresponding transistor, and the epitaxial structures coupled to both ends of the channel (e.g., along the X-direction) can be configured as source/drain structures (or terminals) of the transistor, and the gate structure that overlays (e.g., straddles) the remaining portion of the fin-like structures can be configured as a gate terminal of the transistor. For example, the active regions 310 and the gate structure 330 can form a number of first transistors (e.g., connected in parallel) in the core area; the active regions 320 and the gate structure 334 can form a number of second transistors (e.g., connected in parallel) in the core area; the active regions 350 and the gate structure 370 can form a number of first transistors (e.g., connected in parallel) in the I/O area; and the active regions 360 and the gate structure 374 can form a number of second transistors (e.g., connected in parallel) in the I/O area.

In some embodiments, the transistors formed in the core area may be operated under a lower supply voltage, and the transistors formed in the I/O area may be operated under a higher supply voltage. At least to this end, the gate structures 330 and 334 can have a width in the X-direction (W₁) and the gate structures 370 and 374 can have a width (W₂) in the X-direction, in which the width W₁ is shorter than the width W₂. Accordingly, the gate structure 332 can have a width in the X-direction (W₃) and the gate structure 372 can have a width (W₄) in the X-direction, in which the width W₃ is shorter than the width W₄. As a non-limiting example, the width W₁ may be around 16 nanometers (nm), while the width W₃ may be around 20 nm; and the width W₂ may be around 320 nm, while the width W₄ may be between around 100 nm and 320 nm. Alternatively or additionally, a ratio of the width W₁ to the width W₃ can be characterized around 80%, and a ratio of the width W₂ to the width W₄ can be characterized between around 100% and around 320%.

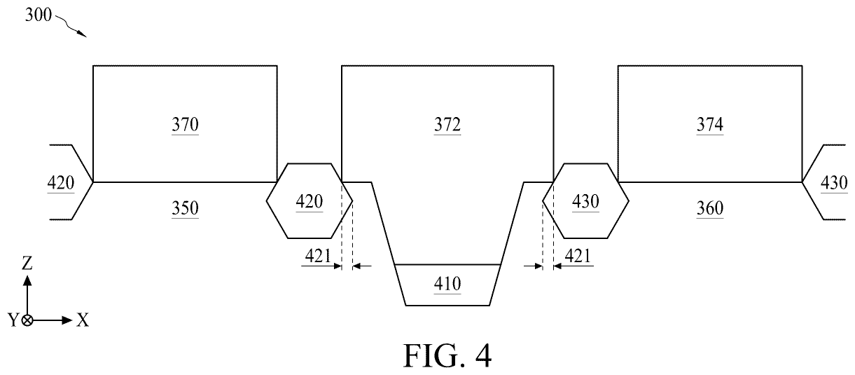

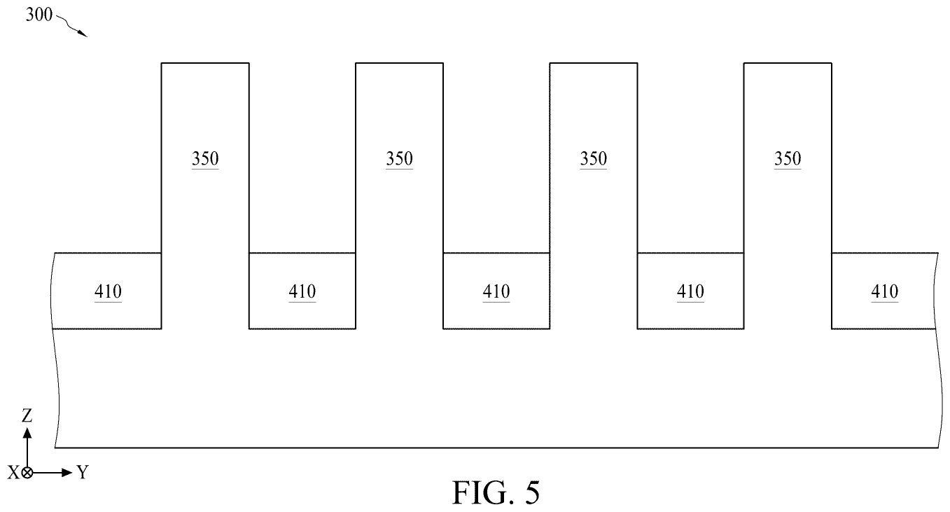

FIG. 4 and FIG. 5 illustrate cross-sectional views of the semiconductor device 300 (FIG. 3), respectively, in accordance with various embodiments. For example, in FIG. 4, the cross-sectional view of the semiconductor device 300 cut along line A-A (FIG. 3) is shown; and in FIG. 5, the cross-sectional view of the semiconductor device 300 cut along line B-B (FIG. 3) is shown. Although only the cross-sectional views in the I/O area are shown in FIGS. 4-5, it should be appreciated that the cross-sectional views in the core area (when formed based on the layout 300) are substantially similar and are thus not repeated.

As shown in FIG. 4, the fin-like structure of the active regions 350 (hereinafter “fin 350”) and the fin-like structure of the active regions 360 (hereinafter “fin 360”) are spaced from each other, with an isolation structure 410 interposed therebetween. Such an isolation structure 410 can be formed to surround a respective lower portion of each of the fin-like structures of the active regions 350-360, which can be better seen in FIG. 5. With this isolation structure 410 (e.g., formed of one or more dielectric materials), the transistors formed by the fins 350 and 360 can be electrically isolated from each other. For example, a transistor, which is formed by the fin 350, the gate structure 370, and epitaxial structures 420, and another transistor, which is formed by the fin 360, the gate structure 374, and epitaxial structures 430, can be isolated by the isolation structure 410.

In various embodiments of the present disclosure, the gate structure 372 can be formed to further overlay the isolation structure 410. For example, in addition to covering a partial top surface of each of the fins 350-360 and extending along the sidewall of each of the fins 350-360, the gate structure 372 can have a bottom surface in contact with the isolation structure 410. Further, in some embodiments (e.g., the illustrative example of FIG. 4), the epitaxial structure 420 formed in the fin 350 may laterally extend beneath the gate structure 372, and the epitaxial structure 430 formed in the fin 360 may laterally extend beneath the gate structure 372.

Stated another way, when viewed from the top, an overlap between the gate structure 372 and each of the “end” epitaxial structures 420 and 430 may be present. As indicated by symbolic arrow 421, the overlap can be measured from a sidewall of the gate structure 372 toward an edge of the active region 350 or 360, in which such an edge of the active region 350 may be defined as the farthest point of the epitaxial structure 420 (between the gate structures 370 and 372) from the gate structure 370, and such an edge of the active region 360 may be defined as the farthest point of the epitaxial structure 420 (between the gate structures 374 and 372) from the gate structure 374. According to one aspect of the present disclosure, such an overlap can be optimized to be less than 20 nm for advantageously reducing the GIDL current (e.g., flowing from the epitaxial structure 420 to the epitaxial structure 430, or vice versa). Alternatively or additionally, a ratio of the overlap to the width of the gate structure 372 (W₄) can be optimized to be less than about 14%.

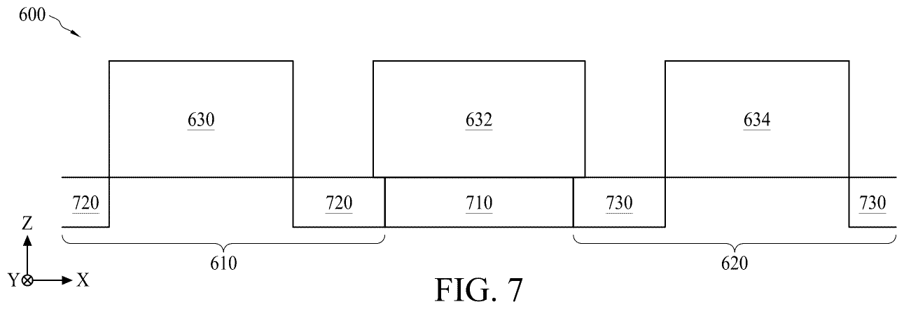

FIG. 6 illustrates a top or layout view 600 for forming an example semiconductor device, which includes a number of structures (e.g., active regions, gate structures) for forming a circuitry, in accordance with various embodiments. Such a semiconductor device may sometimes be referred to as “semiconductor device 600” in the following discussion. FIG. 7 illustrates a cross-sectional view of the semiconductor device 600 cut along line A-A. When compared to the layout 300 (FIG. 3) for forming transistors in a FinFET structure, the layout 600 is configured to form transistors in a planar structure.

In certain aspects, the semiconductor device 600 may be a non-limiting implementation formed based on a portion of a layout configured for forming either the core circuitry or the I/O circuitry on the substrate 120 (FIG. 1). However, it should be appreciated that the layout view of FIG. 6 is merely an example, and thus, the substrate 120 that includes a core circuitry and an I/O circuitry can be configured in any of various other implementations while remaining within the scope of the present disclosure.

As shown in FIG. 6, the layout 600 includes active regions 610 and 620, and a number of gate structures 630, 632, and 634. It should be understood that the layout 600 can include any number of the same or other patterns to form respective active regions or gate structures, while remaining within the scope of present disclosure. The active regions 610 and 620 can extend along a first lateral direction (e.g., the X-direction), and the gate structures 630, 632, and 634 can each extend along a second lateral direction (e.g., the Y-direction) perpendicular to the first lateral direction.

The gate structures 630 and 634 can traverse the active regions 610 and 620, respectively, while the gate structure 632 can traverse both of the active regions 610 and 620. Specifically, the gate structure 632 can overlay a longitudinal end portion of the active regions 610 (e.g., by covering a portion of a top surface of the active region 610 adjacent one of the ends of the active region 610); and the gate structure 632 can overlay a longitudinal end portion of the active regions 620 (e.g., by covering a portion of a top surface of the active region 620 adjacent one of the ends of the active region 620). In other words, each of the gate structures 630 and 634 can traverse a portion of the corresponding active regions, with a pair of other portions disposed on the lateral sides of itself, while the gate structure 632 can traverse each of the neighboring (yet spaced) active regions, with another portion disposed on one lateral side of itself.

The gate structures 630 and 634 can each correspond to an active (e.g., metal or polysilicon) gate structure, while the gate structure 632 can correspond to a dummy (e.g., metal or polysilicon) gate structure. For example, the gate structures 630 and 634, together with their traversed active regions, can operatively form functional transistors, while the gate structure 632, even with its traversed active regions, may not operatively form a functional transistor. The gate structure 632 is sometimes referred to as a CPODE structure. In some embodiments, the active regions 610-620 and the gate structures 630-634 can be formed along the major surface of a substrate, and are sometimes referred to as part of front-end-of-line (FEOL) processing.

The transistors formed by the active regions and the gate structures of the layout 600, as discussed above, may each be configured as a planar field effect transistor structure. The active regions 610 and the active regions 620 can be spaced apart from each other along the X-direction with a spacing(S). The gate structures 630 and 634 can have a width in the X-direction (W₁) and the gate structure 632 can have a width (W₂) in the X-direction. In one aspect (when the transistors formed by the layout 600 are configured as a part of a core circuitry), a ratio of the width W₁ to the width W₂ can be characterized around 80%. In another aspect (when the transistors formed by the layout 600 are configured as a part of an I/O circuitry), the ratio of the width W₁ to the width W₂ can be characterized between around 100% and around 320%.

As shown in FIG. 7, the active region 610 (e.g., a first well in the substrate) and the active region 620 (e.g., a second well in the substrate) are spaced from each other, with an isolation structure 710 interposed therebetween. Such an isolation structure 710 can be formed to surround each of the active regions 610-620. With this isolation structure 710 (e.g., formed of one or more dielectric materials), the transistors formed by the active regions 610 and 620 can be electrically isolated from each other. For example, a transistor, which is formed by the active region 610, the gate structure 630, and epitaxial structures 720, and another transistor, which is formed by the active region 620, the gate structure 634, and epitaxial structures 730, can be isolated by the isolation structure 710.

In various embodiments of the present disclosure, the gate structure 632 can be formed to overlay the isolation structure 710. For example, the gate structure 632 can have a bottom surface in contact with the isolation structure 710. Further, in some embodiments (e.g., the illustrative example of FIG. 7), the epitaxial structure 720 formed in the active region 610 may laterally extend beneath the gate structure 632, and the epitaxial structure 730 formed in the active region 620 may laterally extend beneath the gate structure 632. Stated another way, when viewed from the top, an overlap between the gate structure 632 and each of the “end” epitaxial structures 720 and 730 may be present. The overlap can be measured from a sidewall of the gate structure 632 toward an edge of the active region 610 or 620. Such an edge of the active region 610 may be defined as the farthest point of the epitaxial structure 720 (between the gate structures 630 and 632) from the gate structure 630, and such an edge of the active region 620 may be defined as the farthest point of the epitaxial structure 730 (between the gate structures 634 and 632) from the gate structure 634. According to one aspect of the present disclosure, such an overlap can be optimized to be less than 20 nm for advantageously reducing the GIDL current (e.g., flowing from the epitaxial structure 720 to the epitaxial structure 730, or vice versa). Alternatively or additionally, a ratio of the overlap to the width of the gate structure 632 (W₂) can be optimized to be less than about 14%.

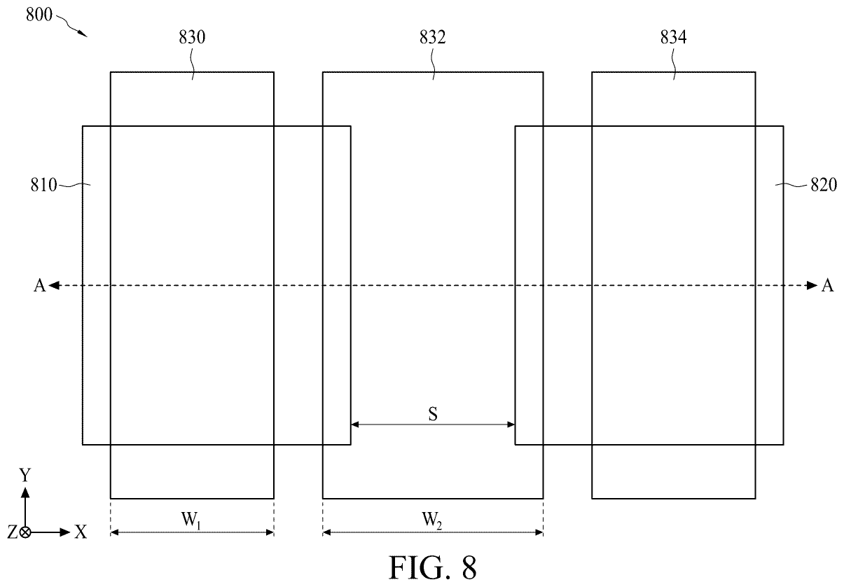

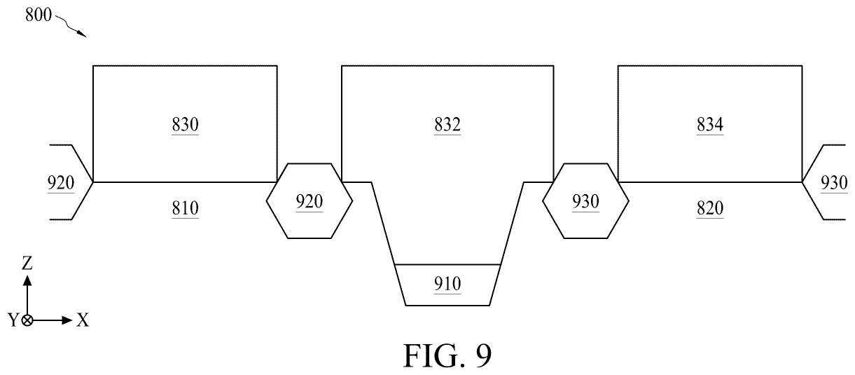

FIG. 8 illustrates a top or layout view 800 for forming an example semiconductor device, which includes a number of structures (e.g., active regions, gate structures) for forming a circuitry, in accordance with various embodiments. Such a semiconductor device may sometimes be referred to as “semiconductor device 800” in the following discussion. FIG. 9 illustrates a cross-sectional view of the semiconductor device 800 cut along line A-A. When compared to the layout 300 (FIG. 3) for forming transistors in a FinFET structure, the layout 800 is configured to form transistors in a mesa structure.

In certain aspects, the semiconductor device 800 may be a non-limiting implementation formed based on a portion of a layout configured for forming either the core circuitry or the I/O circuitry on the substrate 120 (FIG. 1). However, it should be appreciated that the layout view of FIG. 8 is merely an example, and thus, the substrate 120 that includes a core circuitry and an I/O circuitry can be configured in any of various other implementations while remaining within the scope of the present disclosure.

As shown in FIG. 8, the layout 800 includes active regions 810 and 820, and a number of gate structures 830, 832, and 834. It should be understood that the layout 800 can include any number of the same or other patterns to form respective active regions or gate structures, while remaining within the scope of present disclosure. The active regions 810 and 820 can extend along a first lateral direction (e.g., the X-direction), and the gate structures 830, 832, and 834 can each extend along a second lateral direction (e.g., the Y-direction) perpendicular to the first lateral direction.

The gate structures 830 and 834 can traverse the active regions 810 and 820, respectively, while the gate structure 832 can traverse both of the active regions 810 and 820. Specifically, the gate structure 832 can overlay a longitudinal end portion of the active regions 810 (e.g., by covering a portion of a top surface of the active region 810 adjacent one of the ends of the active region 810 and extending along a sidewall of the active region 810 that faces the active region 820); and the gate structure 832 can overlay a longitudinal end portion of the active regions 820 (e.g., by covering a portion of a top surface of the active region 820 adjacent one of the ends of the active region 820 and extending along a sidewall of the active region 820 that faces the active region 810). In other words, each of the gate structures 830 and 834 can traverse a portion of the corresponding active regions, with a pair of other portions disposed on the lateral sides of itself, while the gate structure 832 can traverse each of the neighboring (yet spaced) active regions, with another portion disposed on one lateral side of itself.

The gate structures 830 and 834 can each correspond to an active (e.g., metal or polysilicon) gate structure, while the gate structure 832 can correspond to a dummy (e.g., metal or polysilicon) gate structure. For example, the gate structures 830 and 834, together with their traversed active regions, can operatively form functional transistors, while the gate structure 832, even with its traversed active regions, may not operatively form a functional transistor. The gate structure 832 is sometimes referred to as a CPODE structure. In some embodiments, the active regions 810-820 and the gate structures 830-834 can be formed along the major surface of a substrate, and are sometimes referred to as part of front-end-of-line (FEOL) processing.

The transistors formed by the active regions and the gate structures of the layout 800, as discussed above, may each be configured as a mesa structure. The active regions 810 and the active regions 820 can be spaced apart from each other along the X-direction with a spacing(S). The gate structures 830 and 834 can have a width in the X-direction (W₁) and the gate structure 832 can have a width (W₂) in the X-direction. In one aspect (when the transistors formed by the layout 800 are configured as a part of a core circuitry), a ratio of the width W₁ to the width W₂ can be characterized around 80%. In another aspect (when the transistors formed by the layout 800 are configured as a part of an I/O circuitry), the ratio of the width W₁ to the width W₂ can be characterized between around 100% and around 320%.

As shown in FIG. 9, the active region 810 (e.g., a first mesa protruding from the substrate) and the active region 820 (e.g., a second mesa protruding from the substrate) are spaced from each other, with an isolation structure 910 interposed therebetween. In comparison with the fin-like structure (e.g., 350 and 360 of FIGS. 3-5), the mesa can have a wider width extending in the Y-direction. That is, when compared to a FinFET with the same channel or gate length (extending in the X-direction), a transistor formed of the mesa can have its channel with a bigger area controlled by its gate structure due to the wider channel width (extending in the Y-direction). The isolation structure 910 can be formed to surround a lower portion of each of the active regions 810-820. With this isolation structure 910 (e.g., formed of one or more dielectric materials), the transistors formed by the active regions 810 and 820 can be electrically isolated from each other. For example, a transistor, which is formed by the active region 810, the gate structure 830, and epitaxial structures 920, and another transistor, which is formed by the active region 820, the gate structure 834, and epitaxial structures 930, can be isolated by the isolation structure 910.

In various embodiments of the present disclosure, the gate structure 832 can be formed to further overlay the isolation structure 910. For example, in addition to covering a partial top surface of each of the mesas 810-820 and extending along the sidewall of each of the mesas 810-820, the gate structure 832 can have a bottom surface in contact with the isolation structure 910. Further, in some embodiments (e.g., the illustrative example of FIG. 9), the epitaxial structure 920 formed in the active region 810 may laterally extend beneath the gate structure 832, and the epitaxial structure 930 formed in the active region 820 may laterally extend beneath the gate structure 832. Stated another way, when viewed from the top, an overlap between the gate structure 832 and each of the “end” epitaxial structures 920 and 930 may be present. The overlap can be measured from a sidewall of the gate structure 832 toward an edge of the active region 810 or 820. Such an edge of the active region 810 may be defined as the farthest point of the epitaxial structure 920 (between the gate structures 830 and 832) from the gate structure 830, and such an edge of the active region 820 may be defined as the farthest point of the epitaxial structure 930 (between the gate structures 834 and 832) from the gate structure 834. According to one aspect of the present disclosure, such an overlap can be optimized to be less than 20 nm for advantageously reducing the GIDL current (e.g., flowing from the epitaxial structure 920 to the epitaxial structure 930, or vice versa). Alternatively or additionally, a ratio of the overlap to the width of the gate structure 832 (W₂) can be optimized to be less than about 14%.

In some embodiments, transistors of the core circuitry and the I/O circuitry of an ISP (e.g., formed on the substrate 120, or respectively on the substrates 210 and 220) can be formed in the same transistor structure. In some other embodiments, transistors of the core circuitry and the I/O circuitry of an ISP (e.g., formed on the substrate 120, or respectively on the substrates 210 and 220) can be formed in respectively different transistor structures. For example, the transistors of the core circuitry can be formed in the FinFET structure (e.g., FIGS. 3-5), and the transistors of the I/O circuitry can be formed in the mesa structure (e.g., FIGS. 8-9). In another example, the transistors of the core circuitry can be formed in the FinFET structure (e.g., FIGS. 3-5), and the transistors of the I/O circuitry can be formed in the planar transistor structure (e.g., FIGS. 6-7). In yet anther example, the transistors of the core circuitry and the transistors of the I/O circuitry can both be formed in the FinFET structure (e.g., FIGS. 3-5).

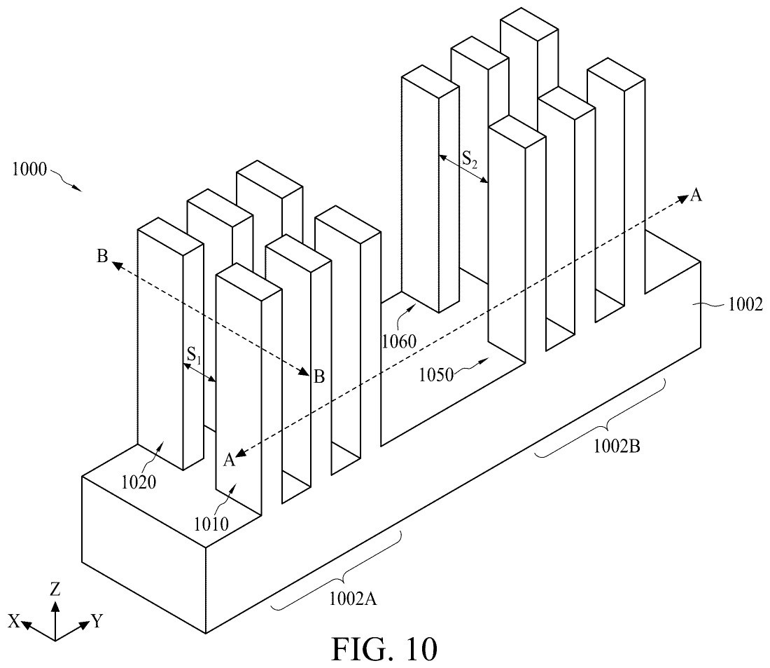

FIG. 10 illustrates a perspective view of an example FinFET structure 1000 at a middle stage of fabrication. In some embodiments, the FinFET structure 1000 may be formed based on the layout 300 shown in FIG. 3. For example, the perspective view of FIG. 10 may be directed to the stage where fins in the core area and the I/O area of a substrate are formed, respectively, which may occur prior to forming an isolation structure or a gate structure. It should be noted that the perspective view of FIG. 10 is provided merely for illustrative purposes, and does not intend to limit the scope of the present disclosure.

For example, the FinFET structure 1000 includes a substrate 1002 with a first area 1002A and a second area 1002B that can correspond to the core area and the I/O area, respectively. In the core area 1002A, the FinFET structure 1000 includes a number of fins 1010 and a number of fins 1020, each of which protrudes above the substrate 1002 in the Z-direction and extends in the X-direction; and in the I/O area 1002B, the FinFET structure 1000 includes a number of fins 1050 and a number of fins 1060, each of which protrudes above the substrate 1002 in the Z-direction and extends in the X-direction. The fins 1010 and 1020 in the core area 1002A may be spaced apart in the X-direction with a spacing (S₁), and the fins 1050 and 1060 in the I/O area 1002B may be spaced apart in the X-direction with a spacing (S₂), where the spacing S₁ is less than the spacing S₂.

In various embodiments, at least a first gate structure (e.g., a CPODE structure), extending along the Y-direction, can be formed to traverse the fins 1010 and 1020. For example, such a first CPODE structure can extend along the space between the fins 1010 and 1020. At least a second gate structure (e.g., another CPODE structure), extending along the Y-direction, can be formed to traverse the fins 1050 and 1060. For example, such a second CPODE structure can extend along the space between the fins 1050 and 1060.

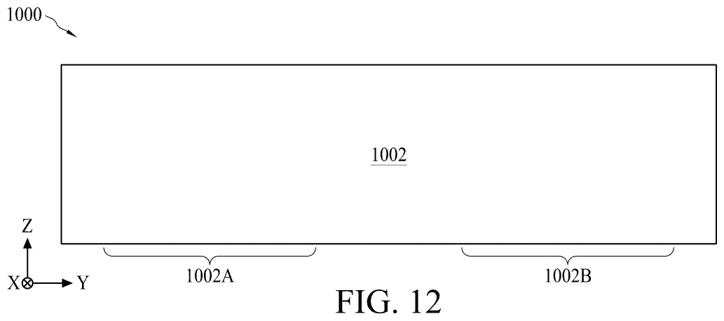

The perspective view of FIG. 10 is provided as a reference to illustrate a number of cross-sectional views in subsequent figures, which correspond to other fabrication stages, respectively. For example, a cross-sectional view, cut along line A-A (or the plane extending in the Y-direction and the Z-direction), extends along the longitudinal axis of a gate structure of the FinFET structure 1000, and a cross-sectional view, cut along line B-B (or the plane extending in the X-direction and the Z-direction), extends along a longitudinal axis of the fins 1010 to 1060 and in a direction of, for example, a current flow between the source/drain structures of corresponding transistors. Subsequent figures (e.g., FIGS. 12-31) refer to these cross-sectional views for clarity.

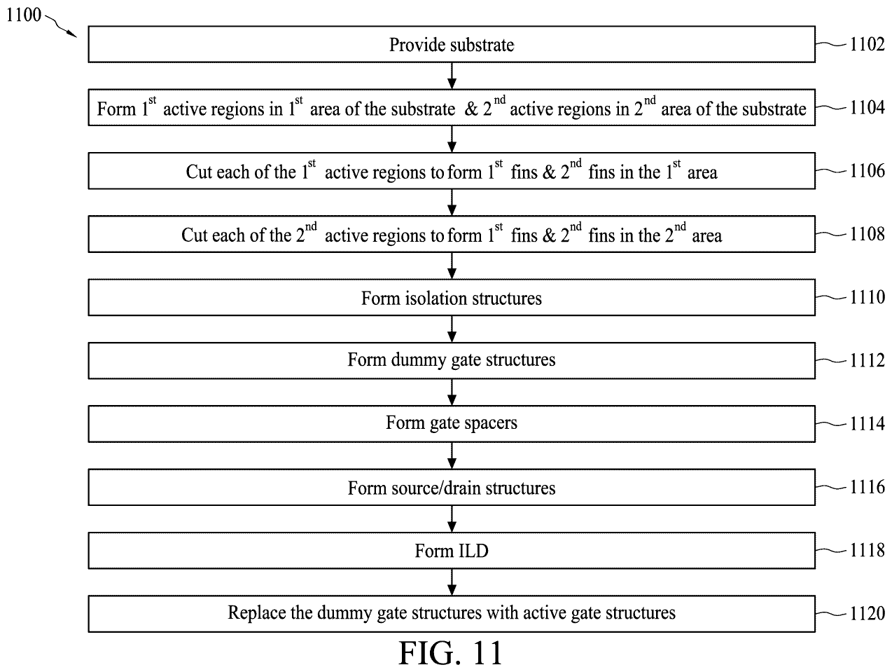

FIG. 11 illustrates a flowchart of a method 1100 for forming a transistor structure with one or more CPODE structures, according to one or more embodiments of the present disclosure. For example, at least some of the operations of the method 1100 can be used to form the FinFET structure 1000. It should be noted that the method 1100 is merely an example, and does not intend to limit the present disclosure. Accordingly, it is understood that additional operations may be provided before, during, and after the method 1100 of FIG. 11, and that some other operations may only be briefly described herein. In some embodiments, operations of the method 1100 may be associated with cross-sectional views of the example FinFET structure 1000 at various fabrication stages as shown in FIGS. 12, 13, 14, 15, 16, 17, 18, 19, 20, 21, 22, 23, 24, 25, 26, 27, 28, 29, 30, and 31, respectively, which will be discussed in further detail below.

Corresponding to operation 1102 of FIG. 11, FIG. 12 is a cross-sectional view of the FinFET structure 1000 including a semiconductor substrate 1002, provided at one of the various stages of fabrication. The cross-sectional view of FIG. 11 is cut along the cross-section A-A indicated in FIG. 10.

As shown in FIG. 12, the substrates 1002 can include area 1002A and area 1002B, configured for forming a core circuitry and an I/O circuitry, respectively. The substrate 1002 may be a semiconductor substrate, such as a bulk semiconductor, a semiconductor-on-insulator (SOI) substrate, or the like, which may be doped (e.g., with a p-type or an n-type dopant) or undoped. The substrate 1002 may be a wafer, such as a silicon wafer. Generally, an SOI substrate includes a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 1002 may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

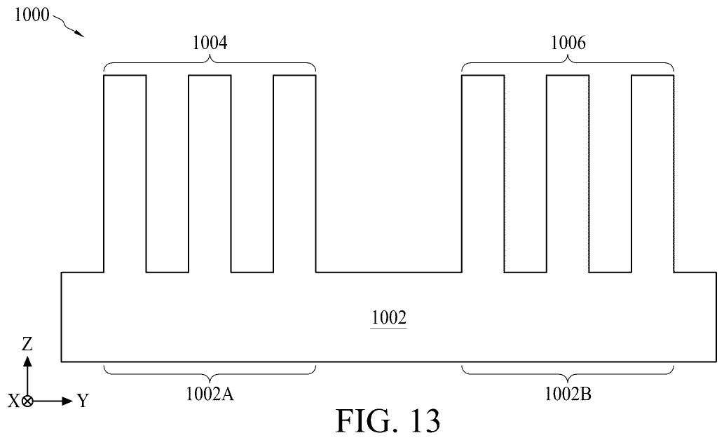

Corresponding to operation 1104 of FIG. 11, FIG. 13 is a cross-sectional view of the FinFET structure 1000 including a number of active regions 1004 in the area 1002A and a number of active regions 1006 in the area 1002B, formed at one of the various stages of fabrication. The cross-sectional view of FIG. 13 is cut along the cross-section A-A indicated in FIG. 10.

In some embodiments, the active regions 1004 can correspond to a combination of the active regions 310 and 320 shown in the layout of FIG. 3, and the active regions 1006 can correspond to a combination of the active regions 350 and 360 shown in the layout of FIG. 3. As will be discussed below (e.g., operations 1106 and 1108), such active regions 1004 and 1006 can each be cut into multiple sections (e.g., fins). Prior to being cut into sections, a layout pattern connecting each of the active regions 310 and a corresponding (e.g., laterally aligned) one of the active regions 320 can be included in the layout 300. Similarly, a layout pattern connecting each of the active regions 350 and a corresponding (e.g., laterally aligned) one of the active regions 360 can be included in the layout 300.

Referring to FIG. 13, the active regions 1004 and active regions 1006 can be extend along the X-direction, with neighboring ones of the active regions 1004 spaced from one another along Y-direction and neighboring ones of the active regions 1006 spaced from one another along Y-direction. In some embodiments, the active regions 1004 and active regions 1006 can be formed by patterning the substrate 1002 using, for example, photolithography and etching techniques. For example, a mask layer, including a pad oxide layer and an overlying pad nitride layer, is formed over the substrate 1002. The pad oxide layer may be a thin film comprising silicon oxide formed, for example, using a thermal oxidation process. The pad oxide layer may act as an adhesion layer between the substrate 1002 and the overlying pad nitride layer. The pad nitride layer can be formed of silicon nitride, silicon oxynitride, silicon carbonitride, the like, or combinations thereof. The pad nitride layer may be formed using a low-pressure chemical vapor deposition (LPCVD) or plasma enhanced chemical vapor deposition (PECVD), for example.

The mask layer may be patterned using photolithography techniques. Generally, photolithography techniques utilize a photoresist material (not shown) that is deposited, irradiated (exposed), and developed to remove a portion of the photoresist material. The remaining photoresist material protects the underlying material, such as the mask layer in this example, from subsequent processing steps, such as etching. For example, the photoresist material is used to pattern the pad oxide layer and pad nitride layer to form a patterned mask.

The patterned mask is subsequently used to pattern exposed portions of the substrate 1002 to form trenches (or openings), each of which is interposed between neighboring ones of the active regions. In some embodiments, the trenches may be formed by etching the substrate 1002 using, for example, reactive ion etch (RIE), neutral beam etch (NBE), the like, or combinations thereof. The etch may be anisotropic. In some embodiments, the trenches may be strips (viewed from the top) parallel to each other, and closely spaced with respect to each other. In some embodiments, the trenches may each be continuous and may surround a corresponding one of the active regions.

The active regions 1004 and active regions 1006 may be patterned by any suitable method. For example, the active regions 1004 and active regions 1006 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the active region.

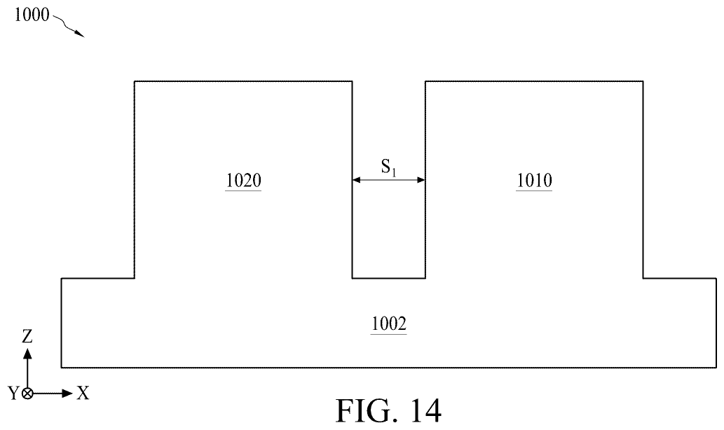

Corresponding to operation 1106 of FIG. 11, FIG. 14 is a cross-sectional view of the FinFET structure 1000 including the fins 1010 and the fins 1020, formed at one of the various stages of fabrication. The cross-sectional view of FIG. 14 is cut along the cross-section B-B indicated in FIG. 10.

As shown in FIG. 14 (and also in the perspective view of FIG. 10), the active regions 1004 in the core area 1002A can be cut or otherwise patterned to form the fins 1010 and 1020. The fin 1010 and the fin 1020 are spaced apart from each other along the X-direction with the spacing (S₁). In some embodiments, each of the fins 1010 and 1020 can be traversed with a number of gate structures to form respective transistors.

In some embodiments, the fins 1010 and 1020 may be formed by etching the active regions 1004 using, for example, reactive ion etch (RIE), neutral beam etch (NBE), the like, or combinations thereof. For example, each of the active regions 1004 can be cut to form at least a pair of the fin 1010 and the fin 1020 that are aligned with each other and spaced from each other along the X-direction. The etch may be anisotropic. The fins 1010 and 1020 may be patterned by any suitable method. For example, the fins 1010 and 1020 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process.

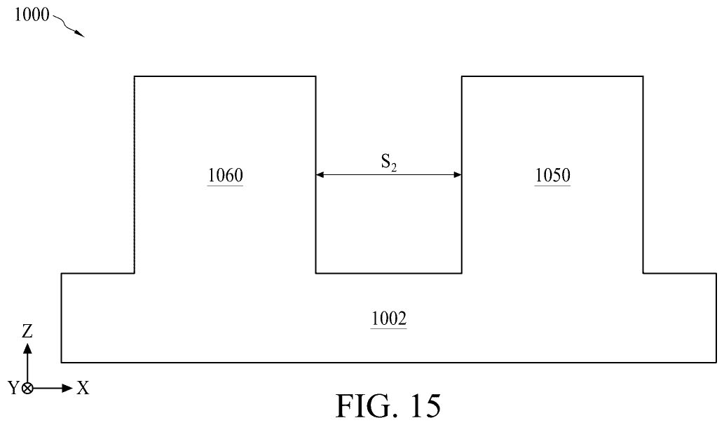

Corresponding to operation 1108 of FIG. 11, FIG. 15 is a cross-sectional view of the FinFET structure 1000 including the fins 1050 and the fins 1060, formed at one of the various stages of fabrication. The cross-sectional view of FIG. 15 is cut along the cross-section B-B indicated in FIG. 10.

As shown in FIG. 15 (and also in the perspective view of FIG. 10), the active regions 1006 in the I/O area 1002B can be cut or otherwise patterned to form the fins 1050 and 1060. The fin 1050 and the fin 1060 are spaced apart from each other along the X-direction with the spacing (S₂). In some embodiments, each of the fins 1050 and 1060 can be traversed with a number of gate structures to form respective transistors.

In some embodiments, the fins 1050 and 1060 may be formed by etching the active regions 1006 using, for example, reactive ion etch (RIE), neutral beam etch (NBE), the like, or combinations thereof. For example, each of the active regions 1006 can be cut to form at least a pair of the fin 1050 and the fin 1060 that are aligned with each other and spaced from each other along the X-direction. The etch may be anisotropic. The fins 1050 and 1060 may be patterned by any suitable method. For example, the fins 1050 and 1060 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process.

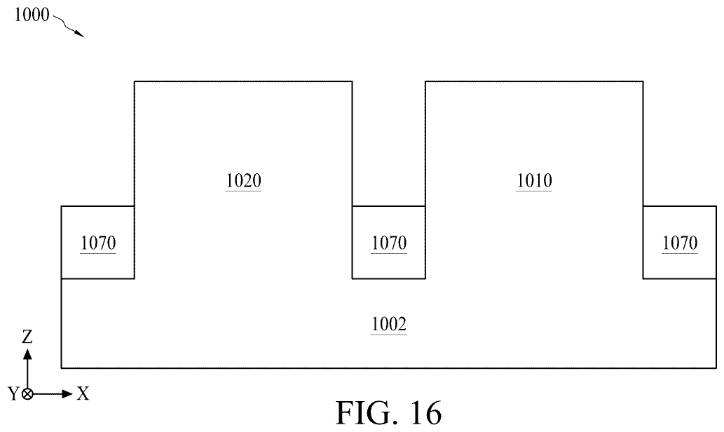

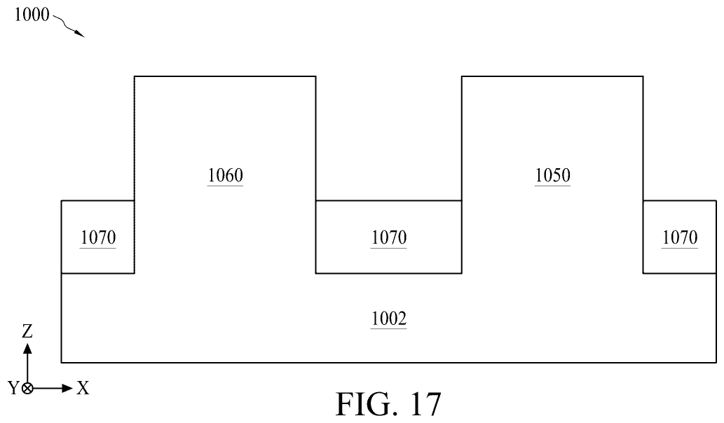

Corresponding to operation 1110 of FIG. 11, FIG. 16 and FIG. 17 are each a cross-sectional view of the FinFET structure 1000 including a number of isolation structures 1070, formed at one of the various stages of fabrication. The cross-sectional view of FIG. 16 corresponds to the core area 1002A, and the cross-sectional view of FIG. 17 corresponds to the I/O area 1002B. The cross-sectional views of FIGS. 16-17 are each cut along the cross-section B-B indicated in FIG. 10.

As shown in FIGS. 16-17, the isolation structures 1070 can surround a lower portion of each of the fins 1010 to 1060. The isolation structures 1070 may each be an oxide, such as silicon oxide, a nitride, the like, or combinations thereof, and may be formed by a high density plasma chemical vapor deposition (HDP-CVD), a flowable CVD (FCVD) (e.g., a CVD-based material deposition in a remote plasma system and post curing to make it convert to another material, such as an oxide), the like, or combinations thereof. Other isolation dielectrics and/or other formation processes may be used. In an example, the isolation structures 1070 each include silicon oxide formed by a FCVD process. The silicon oxide can fill the trenches between the neighboring fins. An anneal process may be performed once the silicon oxide are deposited. Following the deposition process, a (e.g., dry) etch may be performed to recess the deposited silicon oxide, thereby forming the isolation structures 1070 that surrounds the lower portion of each of the fins 1010 to 1060. For example, the dry etch includes using an etchant gas to anisotropically etch the deposited silicon oxide. The etchant gas includes at least one of: chlorine (Cl₂), hydrogen bromide (HBr), carbon tetrafluoride (CF₄), fluoroform (CHF₃), difluoromethane (CH₂F₂), fluoromethane (CH₃F), hexafluoro-1,3-butadiene (C₄F₆), boron trichloride (BCl₃), sulfur hexafluoride (SF₆), hydrogen (H₂), or nitrogen trifluoride (NF₃).

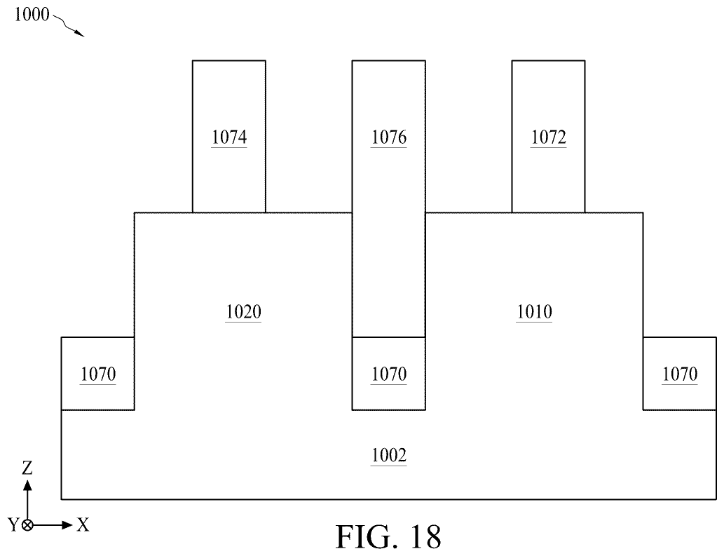

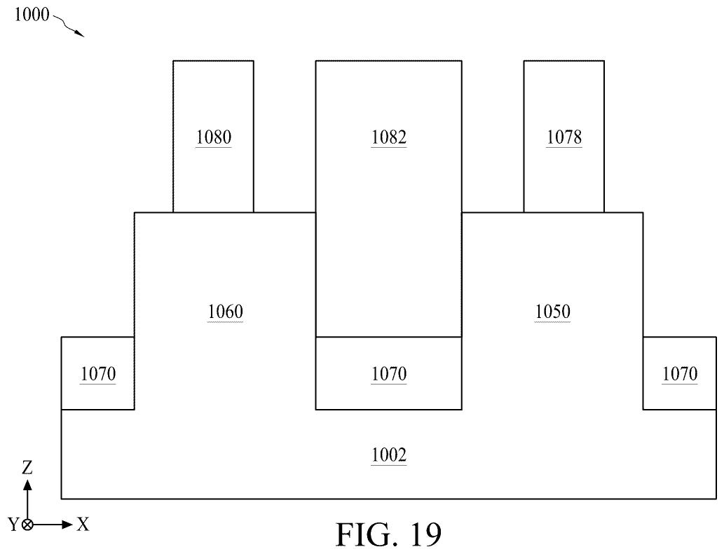

Corresponding to operation 1112 of FIG. 11, FIG. 18 and FIG. 19 are each a cross-sectional view of the FinFET structure 1000 including a number of dummy gate structures 1072, 1074, and 1076, and a number of the dummy gate structures 1078, 1080, and 1082, formed at one of the various stages of fabrication. The cross-sectional view of FIG. 18 corresponds to the core area 1002A, and the cross-sectional view of FIG. 19 corresponds to the I/O area 1002B. The cross-sectional views of FIGS. 18-19 are each cut along the cross-section B-B indicated in FIG. 10.

As shown in FIG. 18, the dummy gate structures 1072 and 1074, extending along the Y-direction, traverse non-edge portions of the fin 1010 and fin 1020, respectively, while the dummy gate structure 1076, also extending along the Y-direction, traverses respective edge portions of the fins 1010 and 1020. Similarly shown in FIG. 19, the dummy gate structures 1078 and 1080, extending along the Y-direction, traverse non-edge portions of the fin 1050 and fin 1060, respectively, while the dummy gate structure 1082, also extending along the Y-direction, traverses respective edge portions of the fins 1050 and 1060.

As such, the dummy gate structure 1076 can have a sidewall with its lower portion in contact with respective sidewalls of the fins 1010 and 1020 that face each other along the X-direction, and the dummy gate structure 1082 can have a sidewall with its lower portion in contact with respective sidewalls of the fins 1050 and 1060 that face each other along the X-direction. Further, the dummy gate structure 1076 can have a bottom surface in contact with a top surface of the isolation structure 1070 interposed between the fins 1010 and 1020, and the dummy gate structure 1082 can have a bottom surface in contact with a top surface of the isolation structure 1070 interposed between the fins 1050 and 1060.

In some other embodiments, despite not being shown, the dummy gate structure 1076 can further include portions laterally extending away from each other in the X-direction, and the dummy gate structure 1082 can further include portions laterally extending away from each other in the X-direction. As such, in addition to extending along the sidewalls of the fins 1010 and 1020, respectively, the dummy gate structure 1076 can have those portions covering partial top surfaces of the fins 1010 and 1020, respectively; and in addition to extending along the sidewalls of the fins 1050 and 1060, respectively, the dummy gate structure 1082 can have those portions covering partial top surfaces of the fins 1050 and 1060, respectively.

According to various embodiments of the present disclosure, the dummy gate structures 1072 and 1074 and the dummy gate structures 1078 and 1080 can each be replaced with or re-purposed as an active gate structure, while the dummy gate structures 1076 and 1082 may remain as a dummy gate structure. As disclosed herein, the dummy gate structure may refer to a gate structure that is not operatively configured to control or module the amount of current flowing through a corresponding transistor channel, and the active gate structure may refer to a gate structure that is operatively configured to control or module the amount of current flowing through a corresponding transistor channel.

At this fabrication stage (operation 1112), the dummy gate structures 1072 to 1082 may each include a dummy gate dielectric and a dummy gate, in some embodiments. To form the dummy gate structures 1072 to 1082, a dielectric layer is formed on the fins 1010-1020 and 1050-1060. The dielectric layer may be, for example, silicon oxide, silicon nitride, silicon oxynitride, silicon carbide, silicon carbonitride, silicon oxycarbonitride, silicon oxycarbide, multilayers thereof, or the like, and may be deposited or thermally grown. Next, a gate layer is formed over the dielectric layer, and a mask layer is formed over the gate layer. The gate layer may be deposited over the dielectric layer and then planarized, such as by a CMP. The mask layer may be deposited over the gate layer. The gate layer may be formed of, for example, polysilicon, although other materials may also be used. The mask layer may be formed of, for example, silicon nitride or the like. After the layers (e.g., the dielectric layer, the gate layer, and the mask layer) are formed, the mask layer may be patterned using suitable lithography and etching techniques to form a mask. The patterns of the mask then may be transferred to the gate layer and the dielectric layer by a suitable etching technique to form the respective dummy gate dielectrics and respective dummy gates of the dummy gate structures 1072 to 1082, as shown.

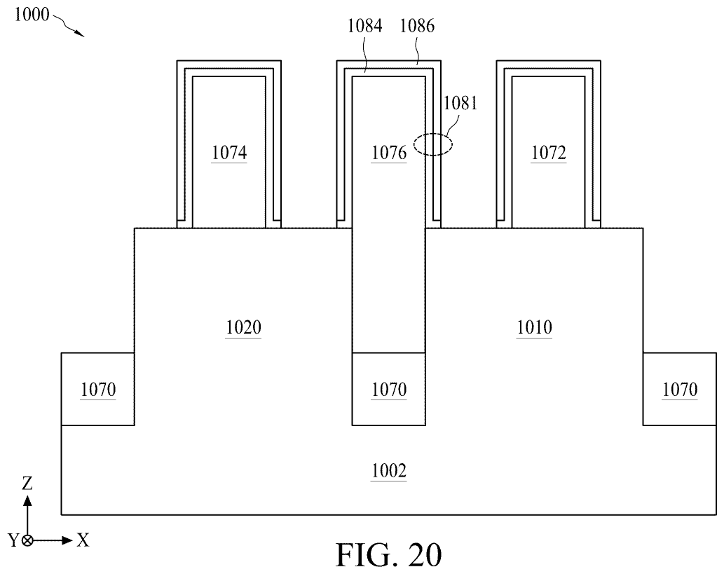

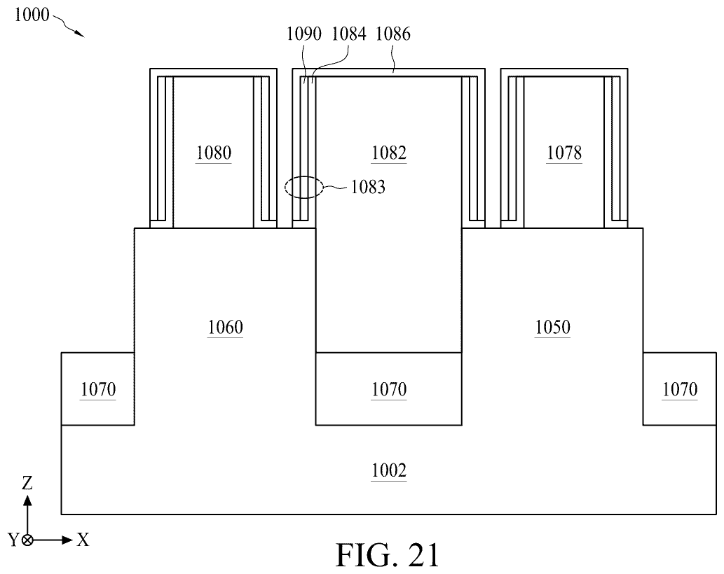

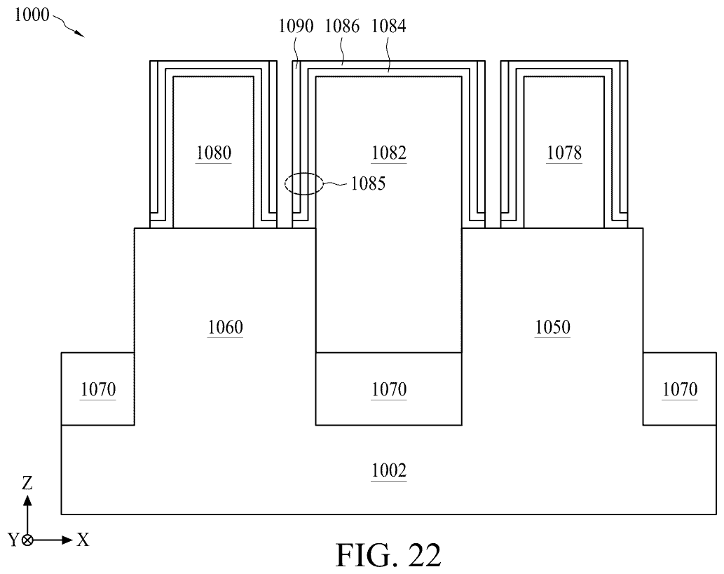

Corresponding to operation 1114 of FIG. 11, FIG. 20, FIG. 21, and FIG. 22 are each a cross-sectional view of the FinFET structure 1000 including a gate spacer (e.g., 1081, 1083, 1085) with multiple layers, formed at one of the various stages of fabrication. The cross-sectional view of FIG. 20 corresponds to the core area 1002A, and the cross-sectional views of FIGS. 21 and 22 correspond to the I/O area 1002B. The cross-sectional views of FIGS. 20-22 are each cut along the cross-section B-B indicated in FIG. 10.

Referring first to FIG. 20, the gate spacer 1081, formed of dielectric layers 1084 and 1086, can be formed to extend along at least sidewalls of each of the dummy gate structures 1072 to 1076 in the core area 1002A. In some embodiments, the dielectric layer 1084 can have an L-shaped profile around a corner formed by the sidewall of each of the dummy gate structures 1072 to 1076 and the top surface of the fin 1010 or 1020. For example, the dielectric layer 1084 can have a first L-shaped profile around the corner formed by one of the sidewalls of the dummy gate structure 1076 and the top surface of the fin 1010, and a second L-shaped profile around the corner formed by the other of the sidewalls of the dummy gate structure 1076 and the top surface of the fin 1020. The dielectric layer 1086 can be disposed over the dielectric layer 1084, each of which can be formed as a conformal layer with a thickness equal to or less than 3 nm. Thus, the dielectric layer 1086 can follow the profile of the dielectric layer 1084. In some embodiments, the dielectric layer 1084 may be formed of silicon oxycarbonitride (SiOCN), and the dielectric layer 1086 may be formed of silicon nitride (SiN).

Referring next to FIG. 21, the gate spacer 1083, formed of the dielectric layers 1084-1086 and additionally a dielectric layer 1090, can be formed to extend along at least sidewalls of each of the dummy gate structures 1078 to 1082 in the I/O area 1002B. In some embodiments, the dielectric layer 1084 can have an L-shaped profile around a corner formed by the sidewall of each of the dummy gate structures 1078 to 1082 and the top surface of the fin 1050 or 1060. For example, the dielectric layer 1084 can have a first L-shaped profile around the corner formed by one of the sidewalls of the dummy gate structure 1082 and the top surface of the fin 1050, and a second L-shaped profile around the corner formed by the other of the sidewalls of the dummy gate structure 1082 and the top surface of the fin 1060. The additional dielectric layer 1090 can be formed over the dielectric layer 1084 to extend along each of the sidewalls of the dummy gate structures 1078 to 1082. Further, a thickness of the dielectric layer 1090 (e.g., between about 4 nm and about 6 nm) can be controlled to allow a lateral portion of the underlying dielectric layer 1084 to extend beyond the dielectric layer 1090. The dielectric layer 1086 can be disposed over the dielectric layer 1090 to extend along each of the sidewalls of the dummy gate structures 1078 to 1082. In some embodiments, the dielectric layer 1090 may be formed of plasma-enhanced oxide (PEOX).

Referring then to FIG. 22, the gate spacer 1085, formed of the dielectric layers 1084-1090, can be formed to extend along at least sidewalls of each of the dummy gate structures 1078 to 1082 in the I/O area 1002B. In some embodiments, the dielectric layer 1084 can have an L-shaped profile around a corner formed by the sidewall of each of the dummy gate structures 1078 to 1082 and the top surface of the fin 1050 or 1060. For example, the dielectric layer 1084 can have a first L-shaped profile around the corner formed by one of the sidewalls of the dummy gate structure 1082 and the top surface of the fin 1050, and a second L-shaped profile around the corner formed by the other of the sidewalls of the dummy gate structure 1082 and the top surface of the fin 1060. The dielectric layer 1086 can be disposed over the dielectric layer 1084 to extend along each of the sidewalls of the dummy gate structures 1078 to 1082. The additional dielectric layer 1090 can be formed over the dielectric layer 1086 to extend along each of the sidewalls of the dummy gate structures 1078 to 1082. Further, a thickness of the dielectric layer 1090 (e.g., between about 4 nm and about 6 nm) can be controlled to allow itself to land on a lateral portion of the underlying dielectric layer 1086.

In some embodiments, the gate spacer 1081 in the core area 1002A (FIG. 20) and the gate spacer 1083 in the I/O area 1002B (FIG. 21) may be concurrently formed by performing at least some of the following processes: a first deposition process (e.g., thermal oxidation, chemical vapor deposition (CVD), or the like) to form a first blanket layer having the same material as the dielectric layer 1084 and covering the dummy gate structures 1072-1082 and the fins 1010-1020 and 1050-1060; a second deposition process (e.g., thermal oxidation, chemical vapor deposition (CVD), or the like) to form a second blanket layer having the same material as the dielectric layer 1090 and covering the dummy gate structures 1072-1082 and the fins 1010-1020 and 1050-1060; a first etch process to remove portions of the dielectric layer 1090 that overlay the top surfaces of the dummy gate structures 1072-1082 and the top surface of the fins 1010-1020 and 1050-1060; covering the dummy gate structures 1078-1082 (with their respective dielectric layers 1090) in the I/O area 1002B, with a second etch process to remove the dielectric layers 1090 in the core area 1002A; and a third deposition process (e.g., thermal oxidation, chemical vapor deposition (CVD), or the like) to form a third blanket layer having the same material as the dielectric layer 1086 and covering the dummy gate structures 1072-1082 and the fins 1010-1020 and 1050-1060.

In some embodiments, the gate spacer 1081 in the core area 1002A (FIG. 20) and the gate spacer 1085 in the I/O area 1002B (FIG. 22) may be concurrently formed by performing at least some of the following processes: a first deposition process (e.g., thermal oxidation, chemical vapor deposition (CVD), or the like) to form a first blanket layer having the same material as the dielectric layer 1084 and covering the dummy gate structures 1072-1082 and the fins 1010-1020 and 1050-1060; a second deposition process (e.g., thermal oxidation, chemical vapor deposition (CVD), or the like) to form a second blanket layer having the same material as the dielectric layer 1086 and covering the dummy gate structures 1072-1082 and the fins 1010-1020 and 1050-1060; a third deposition process (e.g., thermal oxidation, chemical vapor deposition (CVD), or the like) to form a third blanket layer having the same material as the dielectric layer 1090 and covering the dummy gate structures 1072-1082 and the fins 1010-1020 and 1050-1060; a first etch process to remove portions of the dielectric layer 1090 that overlay the top surfaces of the dummy gate structures 1072-1082 and the top surface of the fins 1010-1020 and 1050-1060; and covering the dummy gate structures 1078-1082 (with their respective dielectric layers 1090) in the I/O area 1002B, with a second etch process to remove the dielectric layers 1090 in the core area 1002A and.

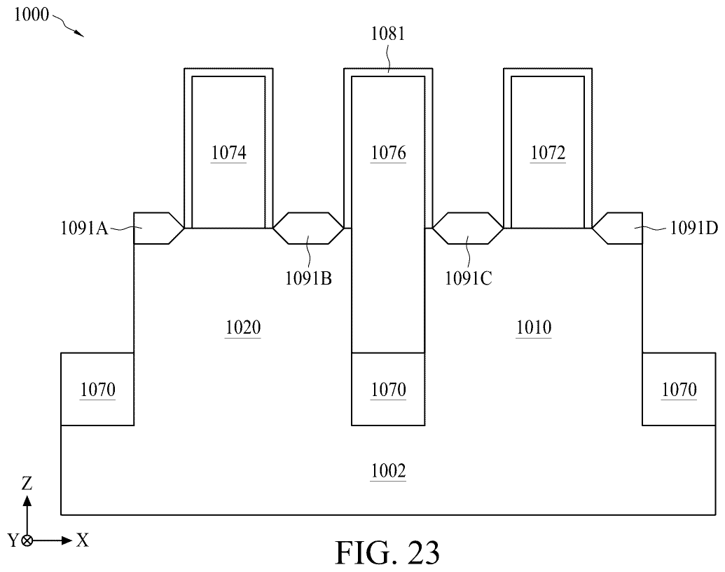

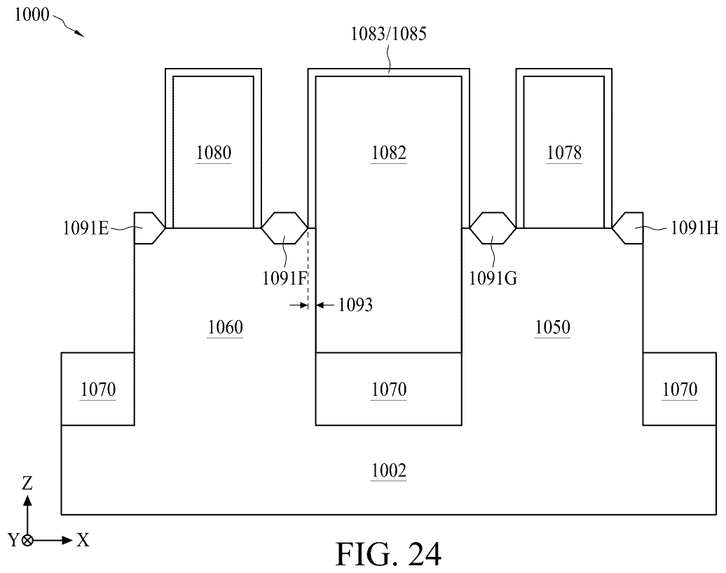

Corresponding to operation 1116 of FIG. 11, FIG. 23 and FIG. 24 are each a cross-sectional view of the FinFET structure 1000 including a number of source/drain structures (e.g., 1091A, 1091B, 1091C, 1091D, 1091E, 1091F, 1091G, 1091H), formed at one of the various stages of fabrication. The cross-sectional view of FIG. 23 corresponds to the core area 1002A, and the cross-sectional view of FIG. 24 corresponds to the I/O area 1002B. The cross-sectional views of FIGS. 23-24 are each cut along the cross-section B-B indicated in FIG. 10.

As shown in FIG. 23, the source/drain structures 1091A to 1091D are formed in recesses of the fin 1010 or 1020 adjacent to a corresponding one of the dummy gate structures 1072-1076. For example, the source/drain structures 1091B and 1091C are formed in the recesses of the fins 1020 and 1010, respectively. The source/drain structures 1091B and 1091C are disposed on the opposite sides of the dummy gate structure 1076, with the gate spacer 1081 interposed therebetween. Similarly in FIG. 24, the source/drain structures 1091E to 1091H are formed in recesses of the fin 1050 or 1060 adjacent to a corresponding one of the dummy gate structures 1078-1082. For example, the source/drain structures 1091F and 1091G are formed in the recesses of the fins 1060 and 1050, respectively. The source/drain structures 1091F and 1091G are disposed on the opposite sides of the dummy gate structure 1082, with the gate spacer 1083 or 1085 interposed therebetween. The recesses are formed by, e.g., an anisotropic etch process using the dummy gate structure as an etching mask, in some embodiments, although any other suitable etching process may also be used.

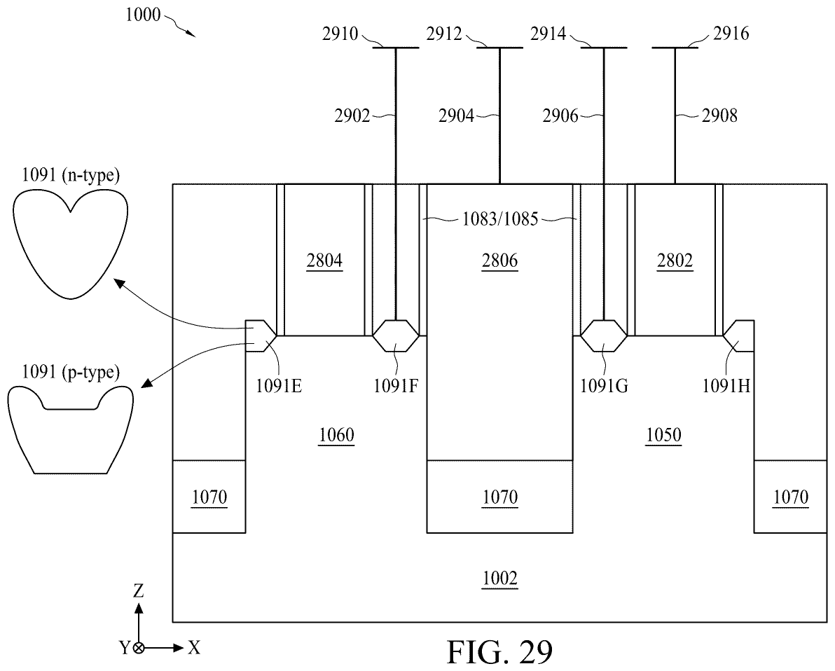

The source/drain structures 1091A to 1091H are formed by epitaxially growing a semiconductor material in the recess (hereinafter “epitaxial source/drain structures 1091A to 1091H”), using suitable methods such as metal-organic CVD (MOCVD), molecular beam epitaxy (MBE), liquid phase epitaxy (LPE), vapor phase epitaxy (VPE), selective epitaxial growth (SEG), the like, or a combination thereof. The epitaxial source/drain structures 1091A to 1091H may have surfaces raised from the top surface of the fin and may have facets. The epitaxial source/drain structures 1091A to 1091H may be implanted with dopants followed by an annealing process. The source/drain structures 1091A to 1091H may have an impurity (e.g., dopant) concentration in a range from about 1×10¹⁹ cm⁻³ to about 1×10²¹ cm⁻³. P-type impurities, such as boron or indium, may be implanted in the source/drain structures of a P-type transistor. N-type impurities, such as phosphorous or arsenide, may be implanted in the source/drain structures of an N-type transistor. In some embodiments, the epitaxial source/drain structures may be in situ doped during their growth. Alternatively or additionally, different conductivity types of the epitaxial source/drain structures 1091A to 1091H may have respective shapes. For example, an n-type epitaxial source/drain structure can have a heart-like shape with a v-shaped bottom surface and a relatively curved top surface, and a p-type epitaxial source/drain structure can have a cupcake-like shape with a flat bottom surface and a relatively flat top surface, which will be shown further in FIGS. 29-31, for example.

Referring again to FIG. 4 where the overlap between a gate structure and an epitaxial (source/drain) structure is defined, with the gate spacer formed along the sidewall of the dummy gate structure, the overlap can be down to about −20 nm. Alternatively or additionally, a ratio of the overlap to the width of the dummy gate structure (e.g., 1082) can be optimized to down to about −14%. For example, in FIG. 24, by controlling a thickness of the gate spacer 1083/1085, the above-defined overlap (which measured from the sidewall of the dummy gate structure 1082 to the farthest point of the epitaxial source/drain structure 1091F as indicated by symbolic arrow 1093) can have a negative value.

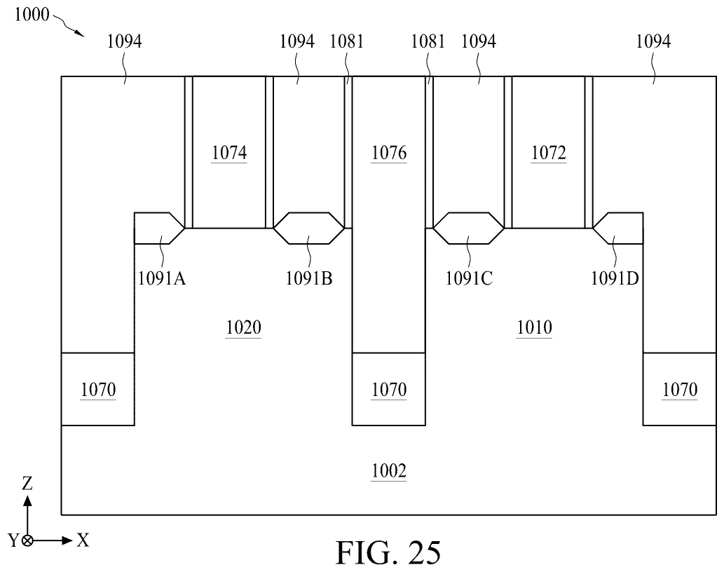

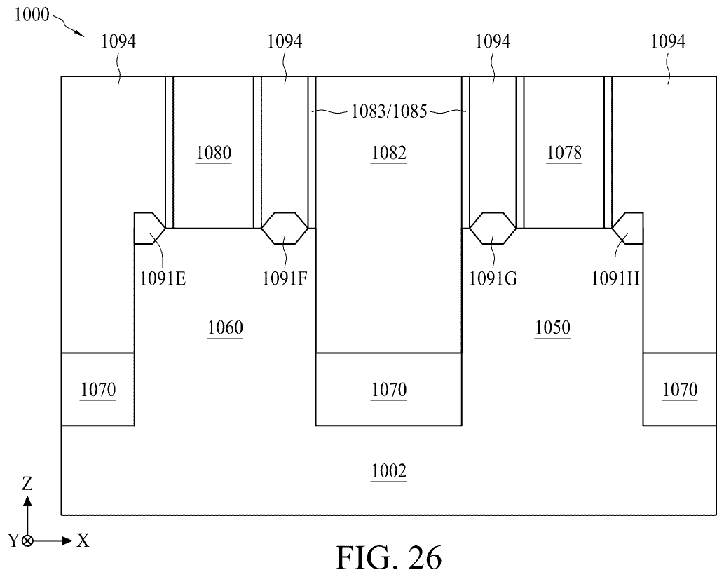

Corresponding to operation 1118 of FIG. 11, FIG. 25 and FIG. 26 are each a cross-sectional view of the FinFET structure 1000 including an interlayer dielectric (ILD) 1094, formed at one of the various stages of fabrication. The cross-sectional view of FIG. 25 corresponds to the core area 1002A, and the cross-sectional view of FIG. 26 corresponds to the I/O area 1002B. The cross-sectional views of FIGS. 25-26 are each cut along the cross-section B-B indicated in FIG. 10.

In some embodiments, prior to forming the ILD 1094, a contact etch stop layer (CESL) can be formed over the structure. The CESL can function as an etch stop layer in a subsequent etching process, and may comprise a suitable material such as silicon oxide, silicon nitride, silicon oxynitride, combinations thereof, or the like, and may be formed by a suitable formation method such as CVD, PVD, combinations thereof, or the like. Next, the ILD 1094 is formed over the CESL and over the dummy gate structures 1072-1082. In some embodiments, the ILD 1094 is formed of a dielectric material such as silicon oxide, phosphosilicate glass (PSG), borosilicate glass (BSG), boron-doped phosphosilicate Glass (BPSG), undoped silicate glass (USG), or the like, and may be deposited by any suitable method, such as CVD, PECVD, or FCVD. After the ILD 1094 is formed, an optional dielectric layer can be formed over the ILD 1094. The dielectric layer can function as a protection layer to prevent or reduces the loss of the ILD 1094 in subsequent etching processes. The dielectric layer may be formed of a suitable material, such as silicon nitride, silicon carbonitride, or the like, using a suitable method such as CVD, PECVD, or FCVD. After the dielectric layer is formed, a planarization process, such as a CMP process, may be performed to achieve a level upper surface for the dielectric layer. The CMP may also remove the mask patterning the dummy gate structures 1072-1082 and portions of the CESL disposed over the dummy gate structures 1072-1082. After the planarization process, the upper surface of the dielectric layer is level with the upper surfaces of the dummy gate structures 1072-1082.

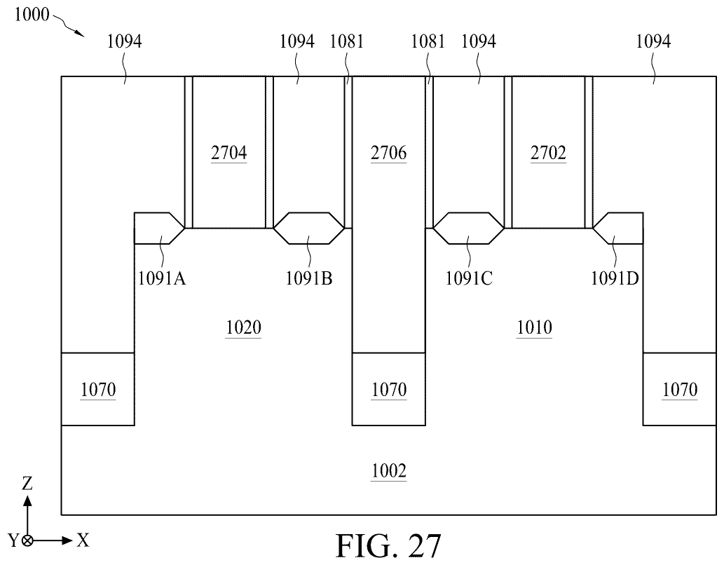

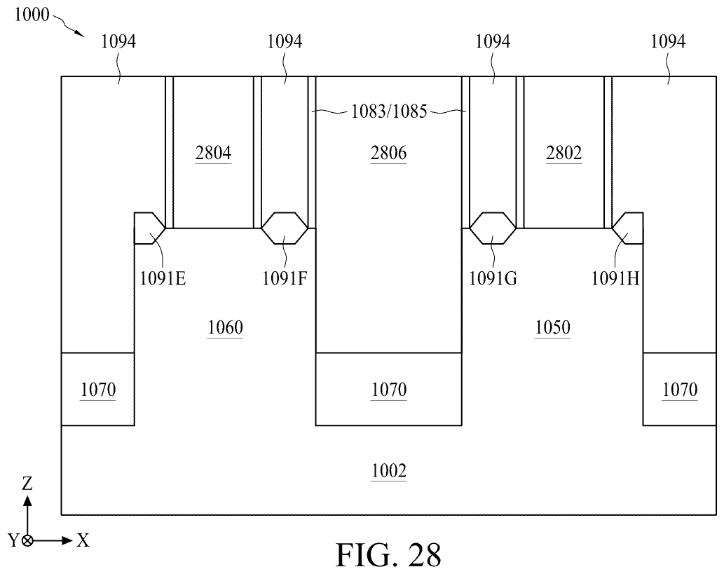

Corresponding to operation 1120 of FIG. 11, FIG. 27 and FIG. 28 are each a cross-sectional view of the FinFET structure 1000 including a number of active/dummy gate structures (e.g., 2702, 2704, 2706, 2802, 2804, 2806), formed at one of the various stages of fabrication. The cross-sectional view of FIG. 27 corresponds to the core area 1002A, and the cross-sectional view of FIG. 28 corresponds to the I/O area 1002B. The cross-sectional views of FIGS. 27-28 are each cut along the cross-section B-B indicated in FIG. 10.

As shown in FIG. 27, the gate structures 2702, 2704, and 2706 may be formed by replacing the dummy gate structures 1072, 1074, and 1076, respectively. In one embodiment, the gate structures 2702 to 2706 can replace the dummy gate structures 1072 to 1076, respectively, with the gate structures 2702-2704 each functioning as an active gate structure and the gate structure 2706 still functioning as a dummy gate structure. In another embodiment, the gate structures 2702 and 2704 can replace the dummy gate structures 1072 and 1074, respectively, with the original dummy gate structure 1076 unchanged. As such, the gate structures 2702-2704 each function as an active gate structure, and the gate structure 2706 (which is the original dummy gate structure 1076) still functions as a dummy gate structure.

Similarly in FIG. 28, the gate structures 2802, 2804, and 2806 may be formed by replacing the dummy gate structures 1078, 1080, and 1082, respectively. In one embodiment, the gate structures 2802 to 2806 can replace the dummy gate structures 1078 to 1082, respectively, with the gate structures 2802-2804 each functioning as an active gate structure and the gate structure 2806 still functioning as a dummy gate structure. In another embodiment, the gate structures 2802 and 2804 can replace the dummy gate structures 1078 and 1080, respectively, with the original dummy gate structure 1082 unchanged. As such, the gate structures 2802-2804 each function as an active gate structure, and the gate structure 2806 (which is the original dummy gate structure 1082) still functions as a dummy gate structure.

The gate structures 2702 to 2806, if replacing the original dummy gate structures, can each include a gate dielectric layer, a metal gate layer, and one or more other layers (e.g., a capping layer, a glue layer) that are not shown for clarity. The gate dielectric layer includes silicon oxide, silicon nitride, or multilayers thereof. In example embodiments, the gate dielectric layer includes a high-k dielectric material, and in these embodiments, the gate dielectric layer may have a k value greater than about 7.0, and may include a metal oxide or a silicate of Hf, Al, Zr, La, Mg, Ba, Ti, Pb, or combinations thereof. The formation methods of gate dielectric layer may include molecular beam deposition (MBD), atomic layer deposition (ALD), PECVD, and the like. A thickness of the gate dielectric layer may be between about 8 angstroms (Å) and about 20 Å, as an example.

The metal gate layer is formed over the respective gate dielectric layer. The metal gate layer may be a P-type work function layer, an N-type work function layer, multi-layers thereof, or combinations thereof, in some embodiments. Accordingly, the metal gate layer is sometimes referred to as a work function layer. For example, the metal gate layer may be an N-type work function layer. In the discussion herein, a work function layer may also be referred to as a work function metal. Example P-type work function metals that may be included in the gate structures for P-type devices include TiN, TaN, Ru, Mo, Al, WN, ZrSi₂, MoSi₂, TaSi₂, NiSi₂, WN, other suitable P-type work function materials, or combinations thereof. Example N-type work function metals that may be included in the gate structures for N-type devices include Ti, Ag, TaAl, TaAIC, TiAIN, TaC, TaCN, TaSiN, Mn, Zr, other suitable N-type work function materials, or combinations thereof.

A work function value is associated with the material composition of the work function layer, and thus, the material of the work function layer is chosen to tune its work function value so that a target threshold voltage Vt is achieved in the device that is to be formed. The work function layer(s) may be deposited by CVD, physical vapor deposition (PVD), ALD, and/or other suitable process. The thickness of a P-type work function layer may be between about 8 Å and about 15 Å, and the thickness of an N-type work function layer may be between about 15 Å and about 30 Å, as an example.

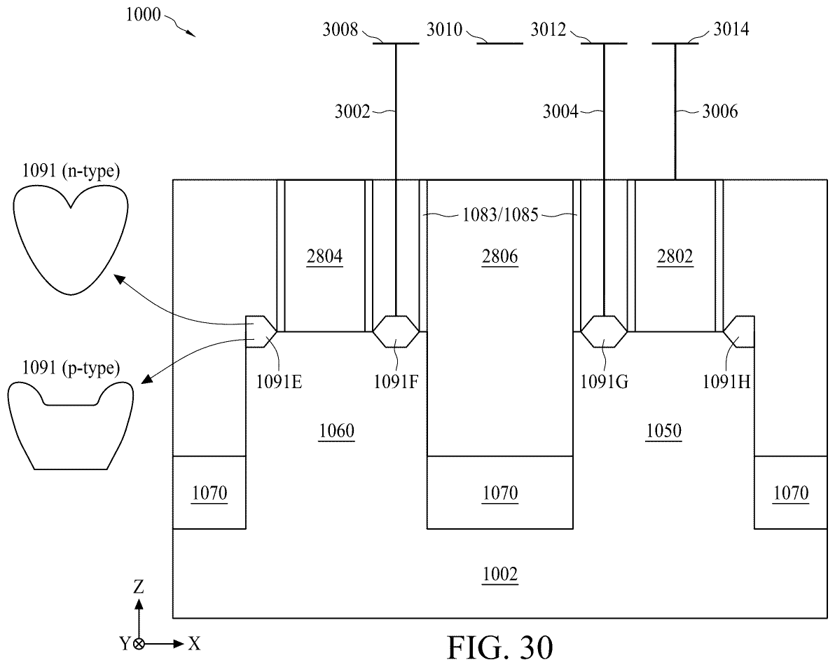

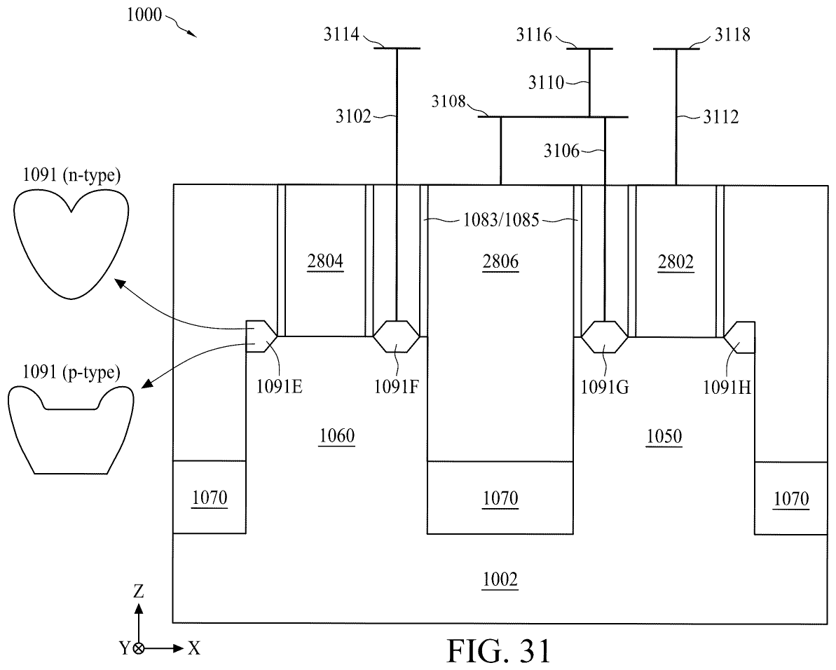

Corresponding to operation 1122 of FIG. 11, FIG. 29, FIG. 30, and FIG. 31 are each a cross-sectional view of the FinFET structure 1000 including a number of interconnect structures, formed at one or more of the various stages of fabrication. Although the cross-sectional views of FIGS. 29 to 31 each correspond to the I/O area 1002B, it should be understood that the FinFET structure 1000 in the core area 1002A can include similar interconnect structures. The cross-sectional views of FIGS. 29-31 are each cut along the cross-section B-B indicated in FIG. 10.

As shown in FIG. 29, the FinFET structure 1000 includes interconnect structures 2902, 2904, 2906, 2908, 2910, 2912, 2914, and 2916. The interconnect structure 2902 can electrically couple the source/drain structure 1091F to the interconnect structure 2910; the interconnect structure 2906 can electrically couple the source/drain structure 1091G to the interconnect structure 2914; the interconnect structure 2904 can electrically couple the dummy gate structure 2806 to the interconnect structure 2912; and the interconnect structure 2908 can electrically couple the active gate structure 2802 to the interconnect structure 2916. In some embodiments, the interconnect structure 2912, electrically coupled to the dummy gate structure 2806, may be tied to a positive voltage (e.g., 1V, 2V, 3V), when the neighboring functional transistors are configured in N-type. As such, the GIDL leakage can be further suppressed.

Although shown as a single segment, each of the interconnect structures 2902 to 2908 can have multiple interconnect structures connected to one another. For example, the interconnect structure 2902 can have a first via structure (sometimes referred to as VD) penetrating the ILD to contact the source/drain structure 1091F and a second via structure (sometimes referred to as V0) to connect the first via structure to the interconnect structure 2910 (sometimes referred to as M1). In another example, the interconnect structure 2904 can have a first contact structure (sometimes referred to as MP) and a second via structure (e.g., V0) to connect the first via structure to the interconnect structure 2912 (e.g., M1). The interconnect structures (VD, MP) are sometimes referred to as part of middle-end-of-line (MEOL) processing, and the interconnect structures (V0, M1) are sometimes referred to as part of back-end-of-line (BEOL) processing. The above-identified interconnect structures can each include tungsten (W), copper (Cu), cobalt (Co), or combinations thereof, and be formed using a dual damascene process.

As shown in FIG. 30, the FinFET structure 1000 includes interconnect structures 3002, 3004, 3006, 3008, 3010, 3012, and 3014. The interconnect structure 3002 can electrically couple the source/drain structure 1091F to the interconnect structure 3008; the interconnect structure 3004 can electrically couple the source/drain structure 1091G to the interconnect structure 3012; the dummy gate structure 2806 may be floating, e.g., electrically isolated from the interconnect structure 3010 disposed thereupon; and the interconnect structure 3006 can electrically couple the active gate structure 2802 to the interconnect structure 3014.

Although shown as a single segment, each of the interconnect structures 3002 to 3006 can have multiple interconnect structures connected to one another. For example, the interconnect structure 3002 can have a first via structure (sometimes referred to as VD) penetrating the ILD to contact the source/drain structure 1091F and a second via structure (sometimes referred to as V0) to connect the first via structure to the interconnect structure 3008 (sometimes referred to as M1). In another example, the interconnect structure 3006 can have a first contact structure (sometimes referred to as MP) and a second via structure (e.g., V0) to connect the first via structure to the interconnect structure 3014 (e.g., M1). The interconnect structures (VD, MP) are sometimes referred to as part of middle-end-of-line (MEOL) processing, and the interconnect structures (V0, M1) are sometimes referred to as part of back-end-of-line (BEOL) processing. The above-identified interconnect structures can each include tungsten (W), copper (Cu), cobalt (Co), or combinations thereof, and be formed using a dual damascene process.

As shown in FIG. 31, the FinFET structure 1000 includes interconnect structures 3102, 3106, 3108, 3110, 3112, 3114, 3116, and 3118. The interconnect structure 3102 can electrically couple the source/drain structure 1091F to the interconnect structure 3114; the interconnect structure 3108 can electrically couple the dummy gate structure 2806 to the source/drain structure 1091G through the interconnect structure 3106, in which the interconnect structure 3108 is further coupled to the interconnect structure 3116 through the interconnect structure 3110; and the interconnect structure 3112 can electrically couple the active gate structure 2802 to the interconnect structure 3118.

Although shown as a single segment, each of the interconnect structures 3102 and 3112 can have multiple interconnect structures connected to one another. For example, the interconnect structure 3102 can have a first via structure (sometimes referred to as VD) penetrating the ILD to contact the source/drain structure 1091F and a second via structure (sometimes referred to as V0) to connect the first via structure to the interconnect structure 3114 (sometimes referred to as M1). In another example, the interconnect structure 3112 can have a first contact structure (sometimes referred to as MP) and a second via structure (e.g., V0) to connect the first via structure to the interconnect structure 3118 (e.g., M1). In some embodiments, the interconnect structure 3108 can be in contact with the dummy gate structure 2806 and further laterally extends to contact the interconnect structure 3106. In some embodiments, the interconnect structure 3108, electrically coupled to the dummy gate structure 2806, may be tied to a positive voltage (e.g., 1V, 2V, 3V), when the neighboring functional transistors are configured in N-type. As such, the GIDL leakage can be further suppressed. The interconnect structure 3108 may sometimes be referred to as MP. The interconnect structures (VD, MP) are sometimes referred to as part of middle-end-of-line (MEOL) processing, and the interconnect structures (V0, M1) are sometimes referred to as part of back-end-of-line (BEOL) processing. The above-identified interconnect structures can each include tungsten (W), copper (Cu), cobalt (Co), or combinations thereof, and be formed using a dual damascene process.

In one aspect of the present disclosure, a semiconductor device is disclosed. The semiconductor device includes a first active region, a second active region, a third active region, and a fourth active region, wherein the first to fourth active regions all extend along a first lateral direction, and wherein the first and second active regions are spaced from each other along the first lateral direction with a first distance, and the third and fourth active regions are spaced from each other along the first lateral direction with a second distance longer than the first distance; a first isolation structure interposed between the first and second active regions along the first lateral direction; a second isolation structure interposed between the third and fourth active regions along the first lateral direction; a first gate structure extending along a second lateral direction perpendicular to the first lateral direction and disposed over the first isolation structure; and a second gate structure extending along the second lateral direction and disposed over the second isolation structure. A first overlap length along the first direction, measured from a first sidewall of the second gate structure toward an edge of the third active region, is configured to be shorter than a threshold, and a second overlap length along the first direction, measured from a second sidewall of the second gate structure toward an edge of the fourth active region, is also configured to be shorter than the threshold.

In another aspect of the present disclosure, a semiconductor device is disclosed. The semiconductor device includes a first wafer operatively configured as a CMOS image sensor (CIS) comprising a plurality of photo diodes; and a second wafer operatively configured as an image signal processor (ISP) bonded to the first wafer. The second wafer includes a first area and a second area disposed next to each other along a first lateral direction. The second wafer, in the first area, comprises a first gate structure extending along a second lateral direction perpendicular to the first lateral direction, wherein the first gate structure is disposed around a first edge of a first active region and a second edge of a second active region, the first and second active regions extending along the first lateral direction and spaced from each other along the first lateral direction. The second wafer, in the second area, comprises a second gate structure extending along the second lateral direction, wherein the second gate structure is disposed around a third edge of a third active region and a fourth edge of a fourth active region, the third and fourth active regions extending along the first lateral direction and spaced from each other along the first lateral direction. The first gate structure has a first width along the first lateral direction and the second gate structure has a second width along the first lateral direction, the first width is substantially shorter than the second width.

In yet another aspect of the present disclosure, a method for fabricating semiconductor devices is disclosed. The method includes forming first active region, a second active region, a third active region, and a fourth active region, wherein the first to fourth active regions all extend along a first lateral direction, and wherein the first and second active regions are spaced from each other along the first lateral direction with a first distance, and the third and fourth active regions are spaced from each other along the first lateral direction with a second distance longer than the first distance; forming a first isolation structure interposed between the first and second active regions along the first lateral direction, and a second isolation structure interposed between the third and fourth active regions along the first lateral direction; and forming a first gate structure extending along a second lateral direction perpendicular to the first lateral direction and disposed over the first isolation structure, and a second gate structure extending along the second lateral direction and disposed over the second isolation structure. A first overlap length along the first direction, measured from a first sidewall of the second gate structure toward an edge of the third active region, is configured to be in a range between about −20 nanometers (nm) and about 20 nm, and a second overlap length along the first direction, measured from a second sidewall of the second gate structure toward an edge of the fourth active region, is also configured to be in the range.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, +20%, or +30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
a first active region, a second active region, a third active region, and a fourth active region, wherein the first to fourth active regions all extend along a first lateral direction, and wherein the first and second active regions are spaced from each other along the first lateral direction with a first distance, and the third and fourth active regions are spaced from each other along the first lateral direction with a second distance longer than the first distance;
a first isolation structure interposed between the first and second active regions along the first lateral direction;
a second isolation structure interposed between the third and fourth active regions along the first lateral direction;
a first gate structure extending along a second lateral direction perpendicular to the first lateral direction and disposed over the first isolation structure; and
a second gate structure extending along the second lateral direction and disposed over the second isolation structure;
wherein a first overlap length along the first direction, measured from a first sidewall of the second gate structure toward an edge of the third active region, is configured to be shorter than a threshold, and a second overlap length along the first direction, measured from a second sidewall of the second gate structure toward an edge of the fourth active region, is also configured to be shorter than the threshold.

2. The semiconductor device of claim 1, wherein the threshold is about 20 nanometers (nm).

3. The semiconductor device of claim 1, wherein the threshold is about 0 nm.

4. The semiconductor device of claim 3, further comprising:
a first spacer and a second spacer extending along the first sidewall and the second sidewall of the second gate structure, respectively;
wherein the first and second spacers are each formed of plasma-enhanced oxide (PEOX).

5. The semiconductor device of claim 4, further comprising:
a first dielectric layer in contact with each of a first sidewall and a second sidewall of the first gate structure;
a second dielectric layer in contact with each of the first sidewall and the second sidewall of the second gate structure;
a third dielectric layer in contact with the first dielectric layer; and
a fourth dielectric layer coupled to the second dielectric layer through the first or second spacer;
wherein the first dielectric layer and the second dielectric layer are each formed of silicon oxycarbonitride (SiOCN), and the third and the fourth dielectric layers are each formed of silicon nitride (SiN).

6. The semiconductor device of claim 4, further comprising:
a first dielectric layer in contact with each of a first sidewall and a second sidewall of the first gate structure;
a second dielectric layer in contact with each of the first sidewall and the second sidewall of the second gate structure;
a third dielectric layer in contact with the first dielectric layer; and
a fourth dielectric layer in contact with the second dielectric layer, with the first or second spacer in contact with the fourth dielectric layer;
wherein the first dielectric layer and the second dielectric layer are each formed of silicon oxycarbonitride (SiOCN), and the third and the fourth dielectric layers are each formed of silicon nitride (SiN).

7. The semiconductor device of claim 1, wherein the first gate structure has a first width along the first lateral direction and the second gate structure has a second width along the first lateral direction, and wherein the second width is substantially greater than the first width.

8. The semiconductor device of claim 7, wherein a ratio of the second width to the second distance is between about 1.3 and about 0.7.

9. The semiconductor device of claim 8, wherein the second isolation structure filling a space between the third and fourth active regions, and the space has a width along the first lateral direction that is approximately equal to the second distance.

10. The semiconductor device of claim 1, further comprising a CMOS image sensor (CIS) bonded to an image signal processor (ISP), wherein the ISP includes the first to fourth active regions and the first to second gate structures.

11. A semiconductor device, comprising:
a first wafer operatively configured as a CMOS image sensor (CIS) comprising a plurality of photo diodes; and
a second wafer operatively configured as an image signal processor (ISP) bonded to the first wafer;
wherein the second wafer includes a first area and a second area disposed next to each other along a first lateral direction;
wherein the second wafer, in the first area, comprises:
a first gate structure extending along a second lateral direction perpendicular to the first lateral direction, wherein the first gate structure is disposed around a first edge of a first active region and a second edge of a second active region, the first and second active regions extending along the first lateral direction and spaced from each other along the first lateral direction;
wherein the second wafer, in the second area, comprises:
a second gate structure extending along the second lateral direction, wherein the second gate structure is disposed around a third edge of a third active region and a fourth edge of a fourth active region, the third and fourth active regions extending along the first lateral direction and spaced from each other along the first lateral direction; and
wherein the first gate structure has a first width along the first lateral direction and the second gate structure has a second width along the first lateral direction, the first width is substantially shorter than the second width.

12. The semiconductor device of claim 11, wherein a first overlap length along the first direction, measured from a first sidewall of the second gate structure toward the third edge of the third active region, is shorter than a threshold, and a second overlap length along the first direction, measured from a second sidewall of the second gate structure toward the fourth edge of the fourth active region, is also shorter than the threshold.

13. The semiconductor device of claim 12, wherein the threshold is about 20 nanometers (nm).

14. The semiconductor device of claim 12, wherein the threshold is about 0 nm.

15. The semiconductor device of claim 14, further comprising:
a first spacer and a second spacer extending along a first sidewall and a second sidewall of the second gate structure, respectively;
wherein the first and second spacers are each formed of plasma-enhanced oxide (PEOX).

16. The semiconductor device of claim 15, further comprising:
a first dielectric layer in contact with each of a first sidewall and a second sidewall of the first gate structure;
a second dielectric layer in contact with each of the first sidewall and the second sidewall of the second gate structure;
a third dielectric layer in contact with the first dielectric layer; and
a fourth dielectric layer coupled to the second dielectric layer through the first or second spacer;
wherein the first dielectric layer and the second dielectric layer are each formed of silicon oxycarbonitride (SiOCN), and the third and the fourth dielectric layers are each formed of silicon nitride (SiN).

17. The semiconductor device of claim 15, further comprising:
a first dielectric layer in contact with each of a first sidewall and a second sidewall of the first gate structure;
a second dielectric layer in contact with each of the first sidewall and the second sidewall of the second gate structure;
a third dielectric layer in contact with the first dielectric layer; and
a fourth dielectric layer in contact with the second dielectric layer, with the first or second spacer in contact with the fourth dielectric layer;
wherein the first dielectric layer and the second dielectric layer are each formed of silicon oxycarbonitride (SiOCN), and the third and the fourth dielectric layers are each formed of silicon nitride (SiN).

18. The semiconductor device of claim 11, wherein the first gate structure is disposed directly above a first isolation structure that is interposed between the first and second active regions along the first lateral direction, and the second gate structure is disposed directly above a second isolation structure that is interposed between the third and fourth active regions along the first lateral direction.

19. A method for fabricating semiconductor devices, comprising:
forming first active region, a second active region, a third active region, and a fourth active region, wherein the first to fourth active regions all extend along a first lateral direction, and wherein the first and second active regions are spaced from each other along the first lateral direction with a first distance, and the third and fourth active regions are spaced from each other along the first lateral direction with a second distance longer than the first distance;
forming a first isolation structure interposed between the first and second active regions along the first lateral direction, and a second isolation structure interposed between the third and fourth active regions along the first lateral direction; and
forming a first gate structure extending along a second lateral direction perpendicular to the first lateral direction and disposed over the first isolation structure, and a second gate structure extending along the second lateral direction and disposed over the second isolation structure;
wherein a first overlap length along the first direction, measured from a first sidewall of the second gate structure toward an edge of the third active region, is configured to be in a range between about −20 nanometers (nm) and about 20 nm, and a second overlap length along the first direction, measured from a second sidewall of the second gate structure toward an edge of the fourth active region, is also configured to be in the range.

20. The method of claim 19, wherein the second gate structure has a width along the first lateral direction, and wherein a ratio of the first or second overlap length to the width is in a range of about −14% and about 14%.
